(19) United States
(12) Patent Application Publication
(10) Pub. No.: US 2025/0366011 A1
(43) Pub. Date: Nov. 27, 2025

(54) SEMICONDUCTOR DEVICE AND MANUFACTURING METHODS THEREOF

(71) Applicant: Taiwan Semiconductor Manufacturing Company, Ltd., Hsinchu (TW)

(72) Inventor: Shahaji B. MORE, Hsinchu City (TW)

(21) Appl. No.: 19/293,661

(22) Filed: Aug. 7, 2025

Related U.S. Application Data
(62) Division of application No. 17/654,927, filed on Mar. 15, 2022.

(51) Int. Cl. H10D 30/00; H10D 62/10; H10D 62/13

(52) U.S. Cl. CPC H10D 30/501; H10D 62/116; H10D 62/151

(57) ABSTRACT

Some implementations described herein provide techniques and semiconductor devices in which a buffer region is formed under a source/drain region of a device. The buffer region is configured to reduce, prevent, and/or block migration of dopants from the source/drain region to other areas of the device, such a mesa region of an adjacent fin structure. In some implementations, a sidewall layer is between the buffer region and the mesa region. Additionally, or alternatively, a dielectric region including a dielectric gas may be between the buffer region and the source/drain region.

### RELATED APPLICATION

This application is a divisional of U.S. patent application Ser. No. 17/654,927, filed Mar. 15, 2022, which is incorporated herein by reference in its entirety.

### BACKGROUND

Fin-based transistors, such as fin field effect transistors (finFETs) and nanostructure transistors (e.g., nanowire transistors, nanosheet transistors, gate-all-around (GAA) transistors, multi-bridge channel transistors, nanoribbon transistors), are three-dimensional structures that include a channel region in a fin (or a portion thereof) that extends above a semiconductor substrate as a three-dimensional structure. A gate structure, configured to control a flow of charge carriers within the channel region, wraps around the fin of semiconductor material. As an example, in a finFET, the gate structure wraps around three sides of the fin (and thus the channel region), thereby enabling increased control over the channel region (and therefore switching of the finFET). As another example, in a nanostructure transistor, the gate structure wraps around a plurality of channel regions in a fin structure such that the gate structure surrounds each of the plurality of channel regions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example semiconductor structure described herein.

FIGS. 3A-3U, 4A-4E, 5A-5D, 6A-6C, 7, 8A-8D, 9A, and 9B are diagrams of example implementations described herein.

FIG. 10 is a diagram of example components of one or more devices described herein.

FIG. 11 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A source/drain region of a device, such as a nanostructure transistor, may include a doped epitaxial material. In some cases, dopants from the doped epitaxial material may diffuse into a mesa region of a fin structure included in the device. The dopants may increase electron tunneling within the mesa region to reduce a performance of the device by increasing short channel effects (e.g., drain-induced barrier lowering (DIBL)), increasing an off-current of the device, and increasing leakage within the device.

Some implementations described herein provide techniques and semiconductor devices in which a buffer region is formed under a source/drain region of a device. The buffer region is configured to reduce, prevent, and/or block migration of dopants from the source/drain region to other areas of the device, such as a mesa region of an adjacent fin structure. In some implementations, a sidewall layer is between the buffer region and the mesa region. Additionally, or alternatively, a dielectric region including a dielectric gas may be between the buffer region and the source/drain region.

The sidewall layer and/or the dielectric region may further reduce, prevent, and/or block migration of the dopants from the source/drain region to the other areas of the device. As a result, a performance of the device may be increased by decreasing short channel effects (e.g., DIBL), decreasing an off-current of the device, and decreasing leakage within the device.

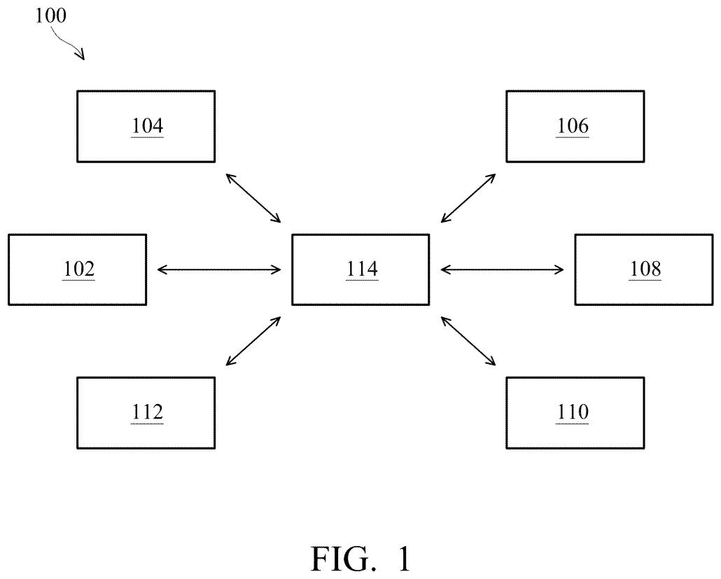

FIG. 1 is a diagram of an example environment 100 in which systems and/or methods described herein may be implemented. As shown in FIG. 1A, environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 etches one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 includes a programmed device that is configured to travel a particular path and/or may operate semi-autonomously or autonomously. In some implementations, the environment 100 includes a plurality of wafer/die transport tools 114.

The wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

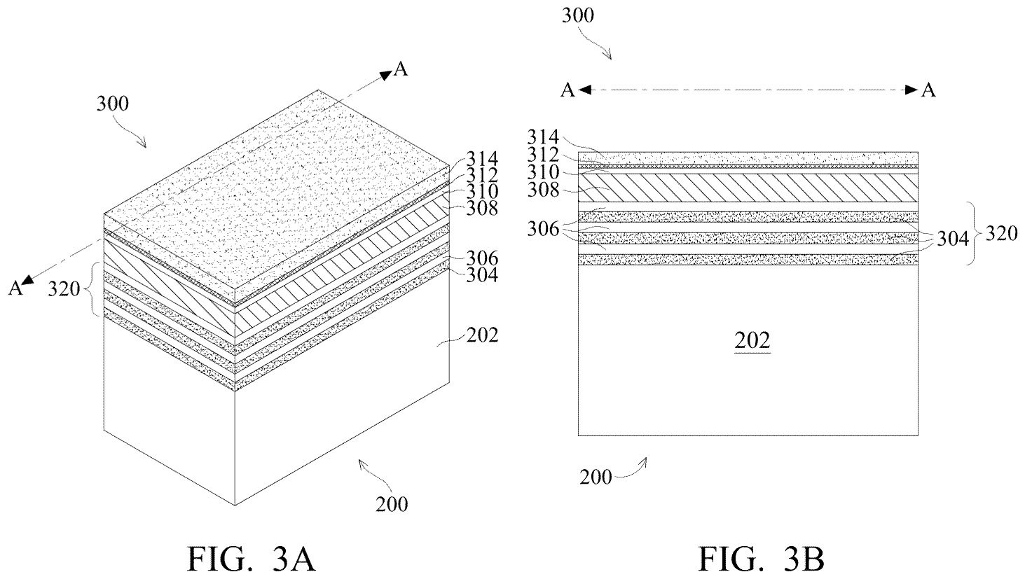

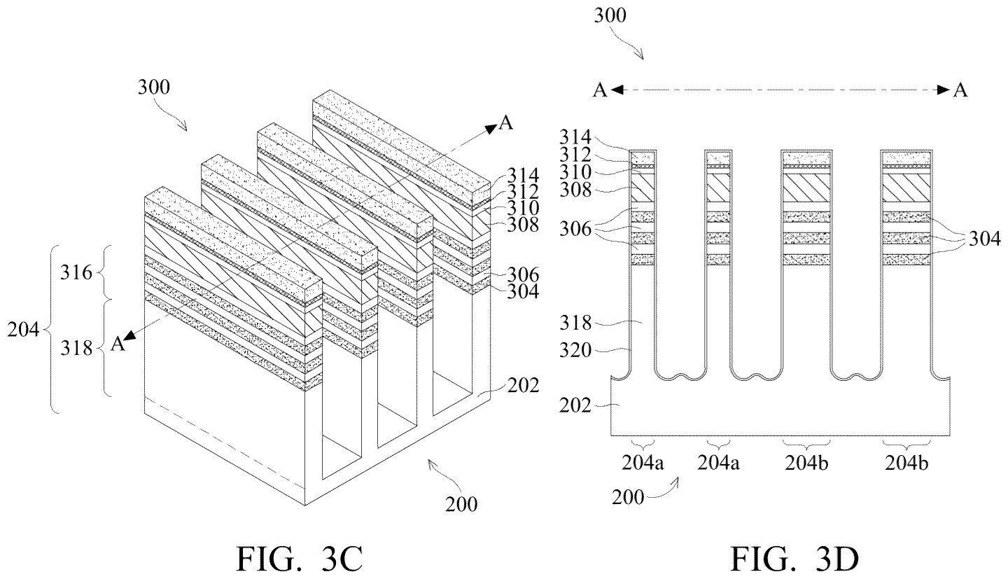

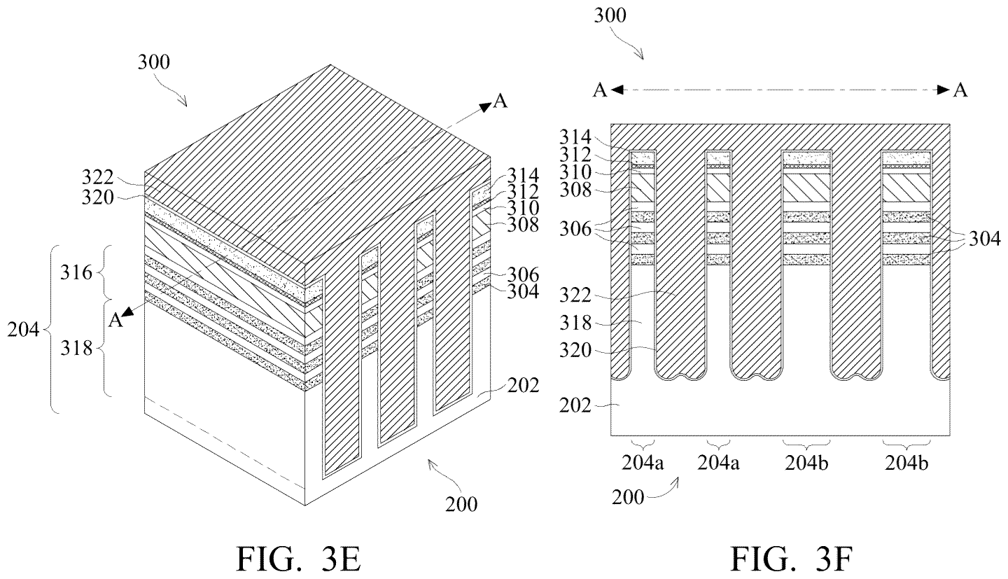

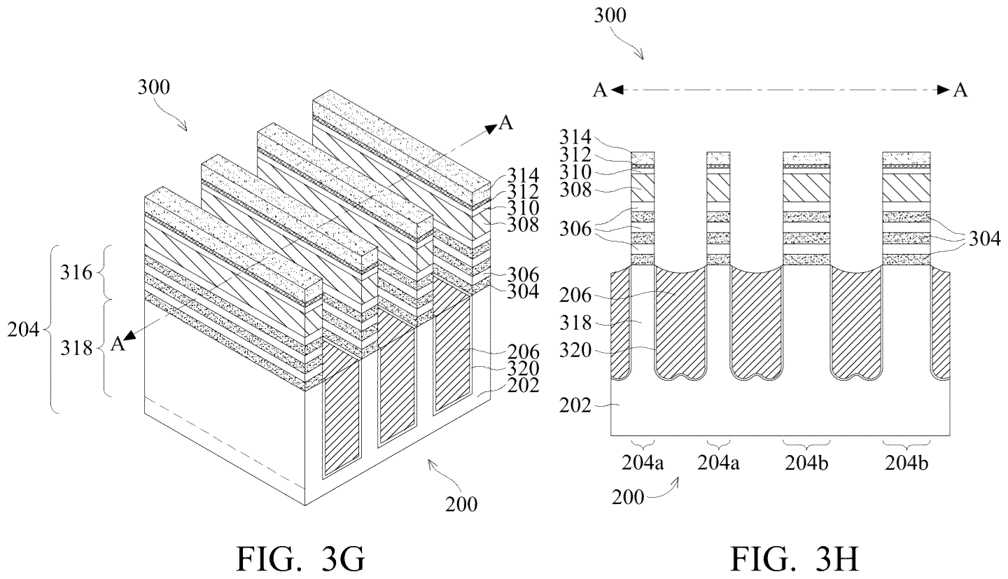

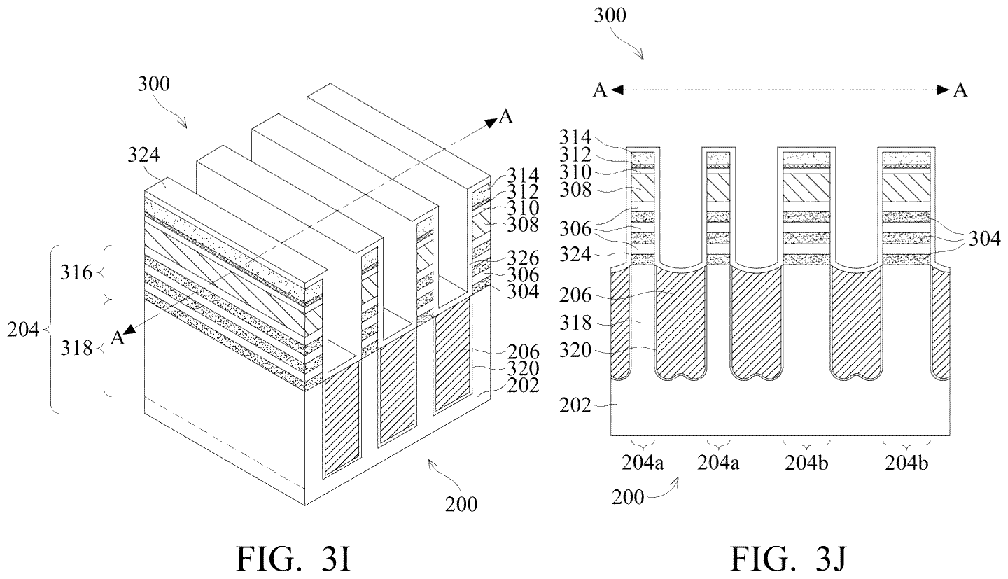

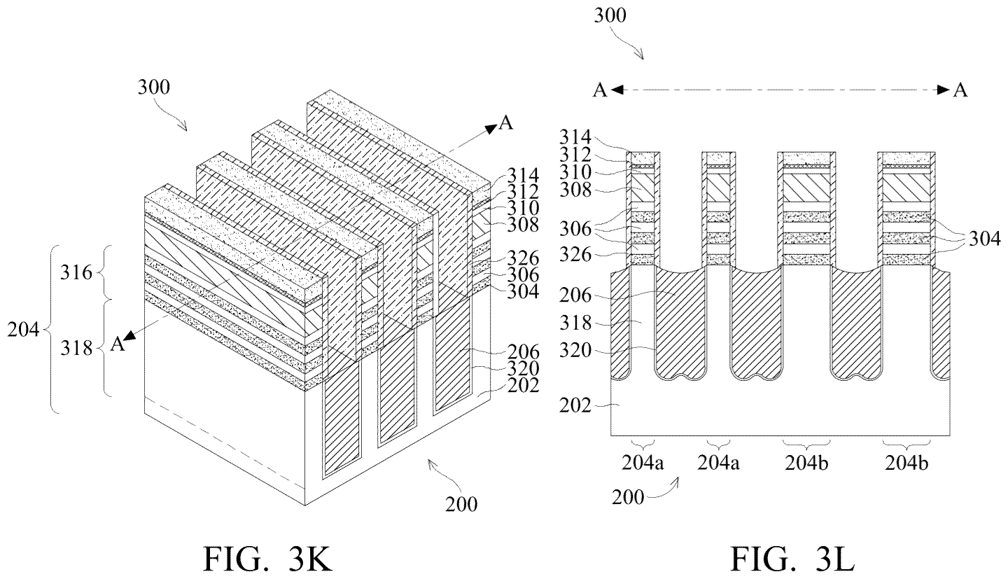

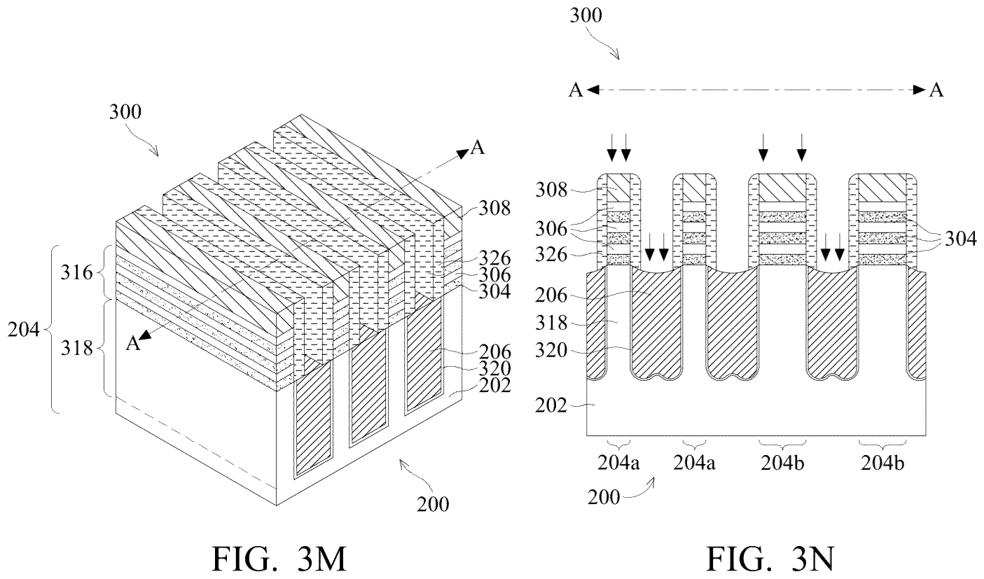

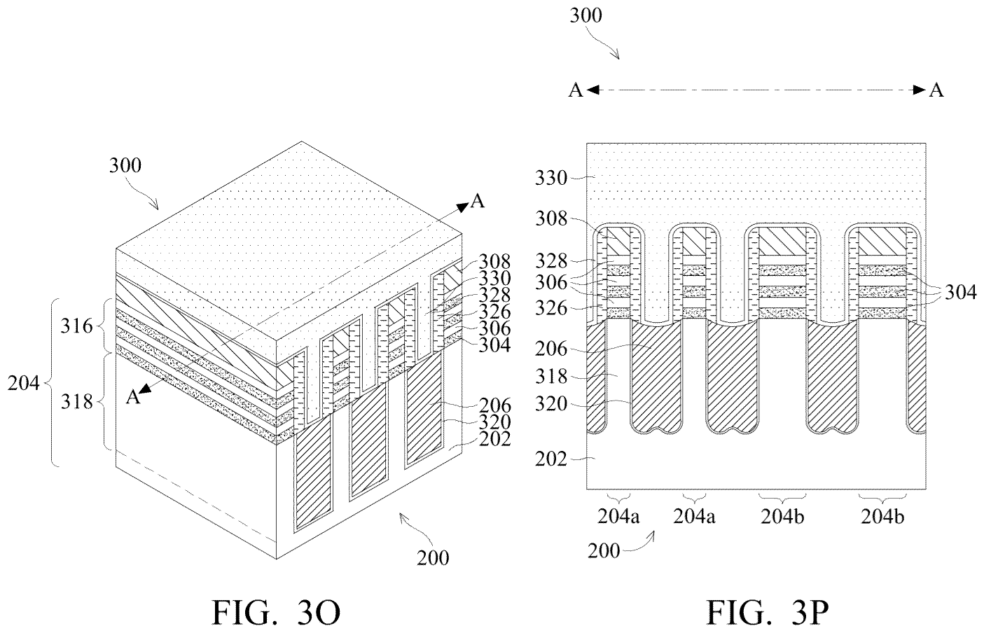

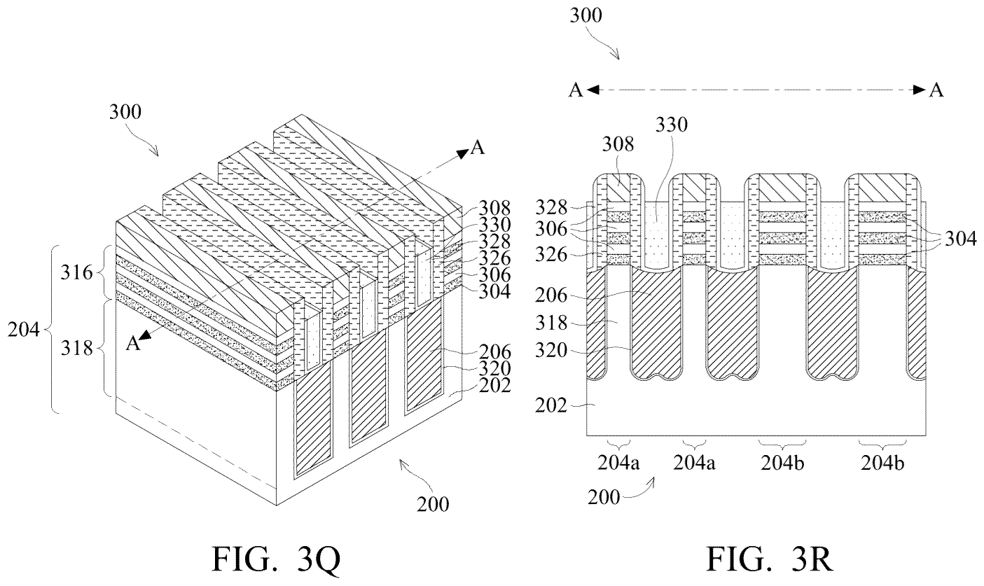

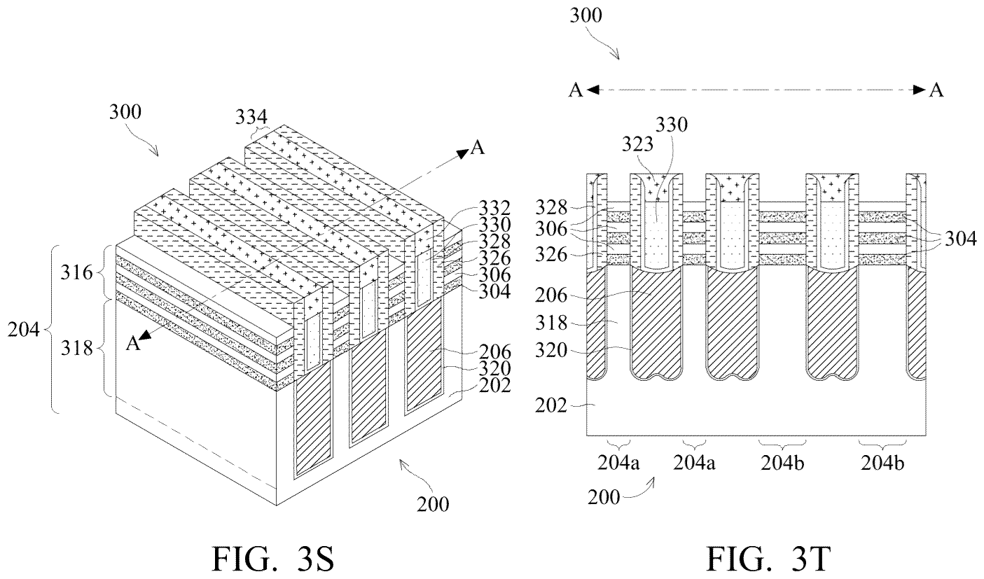

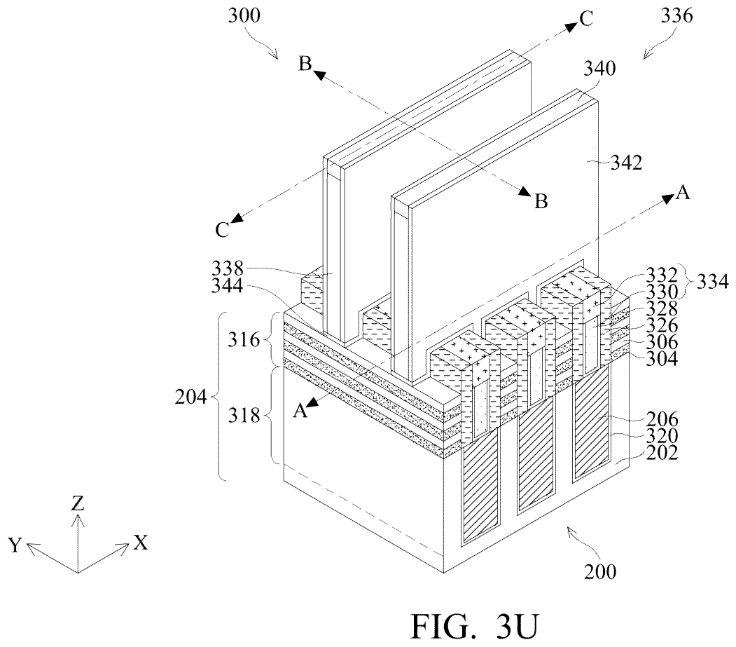

In some implementations, and as described in connection with FIGS. 3A-3U, 4A-4E, 5A-5D, 6A-6C, 7, 8A-8D, 9A, and 9B and elsewhere herein, the semiconductor processing tools 102-112 may perform a method including one or more processing operations to form structures and/or regions of a nanostructure transistor. For example, the method may include forming a fin structure and forming a tapered recess extending into the fin structure between mesa regions of the fin structure. The method further includes forming an inner spacer layer including sidewall portions on portions of opposing sidewalls of the tapered recess. In some implementations, the portions of the opposing sidewalls correspond to sidewalls of the mesa regions. The method further includes forming a first epitaxial layer including a portion between the sidewall portions and forming, above the portion of the first epitaxial layer, a first portion of a second epitaxial layer. The method also includes forming a second portion of the second epitaxial layer above the first portion of the second epitaxial layer such that an air gap is formed between the first portion of the second epitaxial layer and the second portion of the second epitaxial layer.

The number and arrangement of tools shown in FIG. 1 are provided as one or more examples. In practice, there may be additional tools, fewer tools, different tools, or differently arranged tools than those shown in FIG. 1. Furthermore, two or more tools shown in FIG. 1 may be implemented within a single tool, or a single tool shown in FIG. 1 may be implemented as multiple, distributed tools. Additionally, or alternatively, a set of tools (e.g., one or more tools) of environment 100 may perform one or more functions described as being performed by another set of tools of environment 100.

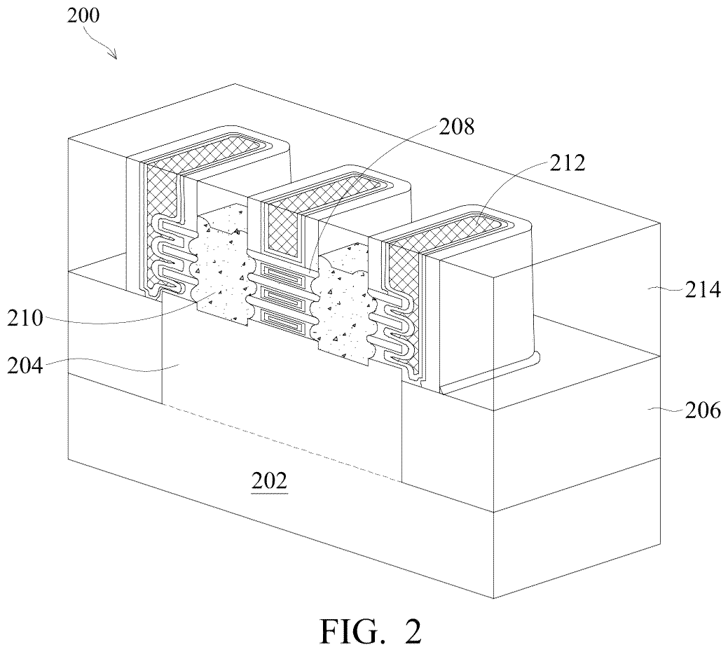

FIG. 2 is a diagram of an example semiconductor device 200 described herein. The semiconductor device 200 includes one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The semiconductor device 200 may include one or more additional devices, structures, and/or layers not shown in FIG. 2. For example, the semiconductor device 200 may include additional layers and/or dies formed on layers above and/or below the portion of the semiconductor device 200 shown in FIG. 2. Additionally, or alternatively, one or more additional semiconductor structures and/or semiconductor devices may be formed in a same layer of an electronic device or integrated circuit (IC) that includes the semiconductor device, with a lateral displacement, as the semiconductor device 200 shown in FIG. 2. FIGS. 3A-3U are schematic cross-sectional views of various portions of the semiconductor device 200 illustrated in FIG. 2, and correspond to various processing stages of forming nanostructure transistors of the semiconductor device 200.

The semiconductor device 200 includes a semiconductor substrate 202. The semiconductor substrate 202 includes a silicon (Si) substrate, a substrate formed of a material including silicon, a III-V compound semiconductor material substrate such as gallium arsenide (GaAs), a silicon on insulator (SOI) substrate, a germanium substrate (Ge), a silicon germanium (SiGe) substrate, a silicon carbide (SiC) substrate, or another type of semiconductor substrate. The semiconductor substrate 202 may include various layers, including conductive or insulating layers formed on a semiconductor substrate. The semiconductor substrate 202 may include a compound semiconductor and/or an alloy semiconductor. The semiconductor substrate 202 may include various doping configurations to satisfy one or more design parameters. For example, different doping profiles (e.g., n-wells, p-wells) may be formed on the semiconductor substrate 202 in regions designed for different device types (e.g., p-type metal-oxide semiconductor (PMOS) nanostructure transistors, n-type metal-oxide semiconductor (NMOS) nanostructure transistors). The suitable doping may include ion implantation of dopants and/or diffusion processes. Further, the semiconductor substrate 202 may include an epitaxial layer (epi-layer), may be strained for performance enhancement, and/or may have other suitable enhancement features. The semiconductor substrate 202 may include a portion of a semiconductor wafer on which other semiconductor devices are formed.

Fin structures 204 are included above (and/or extend above) the semiconductor substrate 202. A fin structure 204 provides a structure on which layers and/or other structures of the semiconductor device 200 are formed, such as epitaxial regions and/or gate structures, among other examples. In some implementations, the fin structures 204 include the same material as the semiconductor substrate 202 and are formed from the semiconductor substrate 202. In some implementations, the fin structures 204 include a silicon (Si) material or another elementary semiconductor material such as germanium (Ge). In some implementations, the fin structures 204 include an alloy semiconductor material such as silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), or a combination thereof.

The fin structures 204 are fabricated by suitable semiconductor process techniques, such as masking, photolithography, and/or etch processes, among other examples. As an example, the fin structures 204 may be formed by etching a portion of the semiconductor substrate 202 away to form recesses in the semiconductor substrate 202. The recesses may then be filled with isolating material that is recessed or etched back to form shallow trench isolation (STI) regions 206 above the semiconductor substrate 202 and between the fin structures 204. Other fabrication techniques for the STI regions 206 and/or for the fin structures 204 may be used. The STI regions 206 may electrically isolate adjacent fin structures 204 and may provide a layer on which other layers and/or structures of the semiconductor device 200 are formed. The STI regions 206 may include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material. The STI regions 206 may include a multi-layer structure, for example, having one or more liner layers.

The semiconductor device 200 includes a plurality of channels 208 that extend between, and are electrically coupled with, source/drain regions 210. The channels 208 include silicon-based nanostructures (e.g., nanosheets or nanowires, among other examples) that function as the semiconductive channels of the nanostructure transistor(s) of the semiconductor device 200. The channels 208 may include silicon germanium (SiGe) or another silicon-based material. The source/drain regions 210 include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the semiconductor device 200 may include p-type metal-oxide semiconductor (PMOS) nanostructure transistors that include p-type source/drain regions 210, n-type metal-oxide semiconductor (NMOS) nanostructure transistors that include n-type source/drain regions 210, and/or other types of nanostructure transistors.

In some implementations, the semiconductor device 200 includes a plurality of types of fin structures. For example, the fin structures 204 may be referred to as active fins in that the channels 208 and source/drain regions 210 are formed and included over the fin structures 204. Another type of fin structure includes hybrid fin structures. The hybrid fin structures may also be referred to as dummy fins, H-fins, or non-active fins, among other examples. Hybrid fin structures may be included between adjacent fin structures 204 (e.g., between adjacent active fin structures). The hybrid fin structures extend in a direction that is approximately parallel to the fin structures 204.

Hybrid fin structures are configured to provide electrical isolation between two or more structures and/or components included in the semiconductor device 200. In some implementations, a hybrid fin structure is configured to provide electrical isolation between two or more fin structures 204 (e.g., two or more active fin structures). In some implementations, a hybrid fin structure is configured to provide electrical isolation between two or more source/drain regions 210. In some implementations, a hybrid fin structure is configured to provide electrical isolation between two or more gate structures or two or more portions of a gate structure. In some implementations, a hybrid fin structure is configured to provide electrical isolation between a source/drain region 210 and a gate structure.

A hybrid fin structure may include a plurality of types of dielectric materials. A hybrid fin structure may include a combination of one or more low dielectric constant (low-k) dielectric materials (e.g., a silicon oxide (SiOₓ) and/or a silicon nitride (SiₓN_{y}), among other examples) and one or more high dielectric constant (high-k) dielectric materials (e.g., a hafnium oxide (HfOₓ) and/or other high-k dielectric material).

At least a subset of the channels 208 extend through one or more gate structures 212. The gate structures 212 may be formed of one or more metal materials, one or more high dielectric constant (high-k) materials, and/or one or more other types of materials. In some implementations, dummy gate structures (e.g., polysilicon (PO) gate structures or another type of gate structures) are formed in place of (e.g., prior to formation of) the gate structures 212 so that one or more other layers and/or structures of the semiconductor device 200 may be formed prior to formation of the gate structures 212. This reduces and/or prevents damage to the gate structures 212 that would otherwise be caused by the formation of the one or more layers and/or structures. A replacement gate process (RGP) is then performed to remove the dummy gate structures and replace the dummy gate structures with the gate structures 212 (e.g., replacement gate structures).

As further shown in FIG. 2, portions of a gate structure 212 are formed in between pairs of channels 208 in an alternating vertical arrangement. In other words, the semiconductor device 200 includes one or more vertical stacks of alternating channels 208 and portions of a gate structure 212, as shown in FIG. 2. In this way, a gate structure 212 wraps around an associated channel 208 on all sides of the channel 208 which increases control of the channel 208, increases drive current for the nanostructure transistor(s) of the semiconductor device 200, and reduces short channel effects (SCEs) for the nanostructure transistor(s) of the semiconductor device 200.

Some source/drain regions 210 and gate structures 212 may be shared between two or more nanoscale transistors of the semiconductor device 200. In these implementations, one or more source/drain regions 210 and a gate structure 212 may be connected or coupled to a plurality of channels 208, as shown in the example in FIG. 2. This enables the plurality of channels 208 to be controlled by a single gate structure 212 and a pair of source/drain regions 210.

The semiconductor device 200 may also include an inter-layer dielectric (ILD) layer 214 above the STI regions 206. The ILD layer 214 may be referred to as an ILD0 layer. The ILD layer 214 surrounds the gate structures 212 to provide electrical isolation and/or insulation between the gate structures 212 and/or the source/drain regions 210, among other examples. Conductive structures such as contacts and/or interconnects may be formed through the ILD layer 214 to the source/drain regions 210 and the gate structures 212 to provide control of the source/drain regions 210 and the gate structures 212.

The semiconductor device 200 may include different combinations of regions and features. As an example, and as described in connection with FIGS. 3A-3U, 4A-4E, 5A-5D, 6A-6C, 7, 8A-8D, 9A, and 9B and elsewhere herein, the semiconductor device 200 may include a plurality of the nanostructure channels 208 over the semiconductor substrate 202. In some implementations, the plurality of nanostructure channels 208 are arranged along a direction perpendicular to the semiconductor substrate 202. The semiconductor device 200 may include a mesa region below the plurality of nanostructure channels 208. The semiconductor device 200 may further include the source/drain region 210 above the buffer region and adjacent to the plurality of nanostructure channels. The semiconductor device 200 may also include a sidewall layer between the buffer region and the mesa region.

Additionally, or alternatively, the semiconductor device 200 may include a plurality of the nanostructure channels 208 over the semiconductor substrate 202. In some implementations, the plurality of nanostructure channels 208 are arranged along a direction perpendicular to the semiconductor substrate 202. The semiconductor device 200 may include a mesa region below the plurality of nanostructure channels 208. The semiconductor device 200 may further include the source/drain region 210 above the buffer region and adjacent to the plurality of nanostructure channels. The semiconductor device 200 may also include a dielectric region, including a gas, between a top surface of the buffer region and a bottom surface of the source/drain region 210.

As indicated above, FIG. 2 is provided as an example. Other examples may differ from what is described with regard to FIG. 2.

FIGS. 3A-3U are diagrams of an example implementation 300 described herein. Operations shown in the example implementation 300 may be performed in a different order than shown in FIGS. 3A-3U. The example implementation 300 includes an example of forming the semiconductor device 200 or a portion thereof (e.g., an example of forming nanostructure transistor(s) of the semiconductor device 200). The semiconductor device 200 may include one or more additional devices, structures, and/or layers not shown in FIGS. 3A-3U. The semiconductor device 200 may include additional layers and/or dies formed on layers above and/or below the portion of the semiconductor device 200 shown in FIGS. 3A-3U. Additionally, or alternatively, one or more additional semiconductor structures and/or semiconductor devices may be formed in a same layer of an electronic device that includes the semiconductor device 200.

FIGS. 3A and 3B respectively illustrate a perspective view of the semiconductor device 200 and a cross-sectional view along the line A-A in FIG. 3A. As shown in FIGS. 3A and 3B, processing of the semiconductor device 200 is performed in connection with the semiconductor substrate 202. A layer stack 302 is formed on the semiconductor substrate 202. The layer stack 302 may be referred to as a superlattice. In some implementations, one or more operations are performed in connection with the semiconductor substrate 202 prior to formation of the layer stack 302. For example, an anti-punch through (APT) implant operation may be performed. The APT implant operation may be performed in one or more regions of the semiconductor substrate 202 above which channels 208 are to be formed. The APT implant operation is performed, for example, to reduce and/or prevent punch-through or unwanted diffusion into the semiconductor substrate 202.

The layer stack 302 includes a plurality of alternating layers. The alternating layers include a plurality of first layers 304 and a plurality of second layers 306. The quantity of the first layers 304 and the quantity of the second layers 306 illustrated in FIGS. 3A and 3B are examples, and other quantities of the first layers 304 and the second layers 306 are within the scope of the present disclosure. In some implementations, the first layers 304 and the second layers 306 are formed to different thicknesses. For example, the second layers 306 may be formed to a thickness that is greater relative to a thickness of the first layers 304. In some implementations, the first layers 304 (or a subset thereof) are formed to a thickness in a range of approximately 4 nanometers to approximately 7 nanometers. In some implementations, the second layers 306 (or a subset thereof) are formed to a thickness in a range of approximately 8 nanometers to approximately 12 nanometers. However, other values for the thickness of the first layers 304 and for the thickness of the second layers 306 are within the scope of the present disclosure.

The first layers 304 include a first material composition, and the second layers 306 include a second material composition. In some implementations, the first material composition and the second material composition are the same material composition. In some implementations, the first material composition and the second material composition are different material compositions. As an example, the first layers 304 may include silicon germanium (SiGe) and the second layers 306 may include silicon (Si). In some implementations, the first material composition and the second material composition have different oxidation rates and/or etch selectivity.

As described herein, the first layers 304 are eventually removed and serve to define a vertical distance between adjacent channels 208 for subsequently-formed nanostructure transistors of the semiconductor device 200. Accordingly, the first layers 304 may also be referred to as sacrificial layers, and the second layers 306 may be referred to as channel layers or as nanostructure channels.

The deposition tool 102 deposits and/or grows the alternating layers to include nanostructures (e.g., nanosheets) on the semiconductor substrate 202. For example, the deposition tool 102 grows the alternating layers by epitaxial growth. However, other processes may be used to form the alternating layers of the layer stack 302. Epitaxial growth of the alternating layers of the layer stack 302 may be performed by a molecular beam epitaxy (MBE) process, a metalorganic chemical vapor deposition (MOCVD) process, and/or another suitable epitaxial growth process. In some implementations, the epitaxially grown layers such as the second layers 306 include the same material as the material of the semiconductor substrate 202. In some implementations, the first layers 304 and/or the second layers 306 include a material that is different from the material of the semiconductor substrate 202. As described above, in some implementations, the first layers 304 include epitaxially grown silicon germanium (SiGe) layers and the second layers 306 include epitaxially grown silicon (Si) layers. Alternatively, the first layers 304 and/or the second layers 306 may include other materials such as germanium (Ge), a compound semiconductor material such as silicon carbide (SiC), gallium arsenide (GaAs), gallium phosphide (GaP), indium phosphide (InP), indium arsenide (IAs), indium antimonide (InSb), an alloy semiconductor such as silicon germanium (SiGe), gallium arsenide phosphide (GaAsP), aluminum indium arsenide (AlInAs), aluminum gallium arsenide (AlGaAs), indium gallium arsenide (InGaAs), gallium indium phosphide (GaInP), gallium indium arsenide phosphide (GaInAsP), and/or a combination thereof. The material(s) of the first layers 304 and/or the material(s) of the second layers 306 may be chosen based on providing different oxidation properties, different etching selectivity properties, and/or other different properties.

As further shown in FIGS. 3A and 3B, the deposition tool 102 may form one or more additional layers over and/or on the layer stack 302. For example, a hard mask (HM) layer 308 may be formed over and/or on the layer stack 302 (e.g., on the top-most second layer 306 of the layer stack 302). As another example, a capping layer 310 may be formed over and/or on the hard mask layer 308. As another example, another hard mask layer including an oxide layer 312 and a nitride layer 314 may be formed over and/or on the capping layer 310. The one or more hard mask (HM) layers 308, 312, and 314 may be used to form one or more structures of the semiconductor device 200. The oxide layer 312 may function as an adhesion layer between the layer stack 302 and the nitride layer 314, and may act as an etch stop layer for etching the nitride layer 314. The one or more hard mask layers 308, 312, and 314 may include silicon germanium (SiGe), a silicon nitride (SiₓN_{y}), a silicon oxide (SiOₓ), and/or another material. The capping layer 310 may include silicon (Si) and/or another material. In some implementations, the capping layer 310 is formed of the same material as the semiconductor substrate 202. In some implementations, the one or more additional layers are thermally grown, deposited by CVD, PVD, ALD, and/or are formed using another deposition technique.

FIGS. 3C and 3D respectively illustrate a perspective view of the semiconductor device 200 and a cross-sectional view along the line A-A in FIG. 3C. As shown in FIGS. 3C and 3D, fin structures 204 are formed above the semiconductor substrate 202 of the semiconductor device 200. A fin structure 204 includes a portion 316 of the layer stack 302 over and/or on a portion (e.g., a mesa region 318) of the fin structure 204 formed in and/or above the semiconductor substrate 202. The fin structures 204 may be formed by any suitable semiconductor processing technique. For example, the fin structures 204 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fin structures.

The fin structures 204 may subsequently be fabricated using suitable processes including photolithography and etch processes. In some implementations, the deposition tool 102 forms a photoresist layer over and/or on the hard mask layer including the oxide layer 312 and the nitride layer 314, the exposure tool 104 exposes the photoresist layer to radiation (e.g., deep ultraviolet (UV) radiation, extreme UV (EUV) radiation), a post-exposure bake process is performed (e.g., to remove residual solvents from the photoresist layer), and the developer tool 106 develops the photoresist layer to form a masking clement (or pattern) in the photoresist layer. In some implementations, patterning the photoresist layer to form the masking element is performed using an electron beam (e-beam) lithography process. The masking element may then be used to protect portions of the semiconductor substrate 202 and portions the layer stack 302 in an etch operation such that the portions of the semiconductor substrate 202 and portions the layer stack 302 remain non-etched to form the fin structures 204. Unprotected portions of the substrate and unprotected portions of the layer stack 302 are etched (e.g., by the etch tool 108) to form trenches in the semiconductor substrate 202. The etch tool may etch the unprotected portions of the substrate and unprotected portions of the layer stack 302 using a dry etch technique (e.g., reactive ion etching), a wet etch technique, and/or a combination thereof.

In some implementations, another fin formation technique is used to form the fin structures 204. For example, a fin region may be defined (e.g., by mask or isolation regions) and, and the portions 316 may be epitaxially grown in the form of the fin structure 204. In some implementations, forming the fin structures 204 includes a trim process to decrease the width of the fin structures 204. The trim process may include wet and/or dry etching processes, among other examples.

As further shown in FIG. 3D, fin structures 204 may be formed for different types of nanostructure transistors for the semiconductor device 200. In particular, a first subset of fin structures 204a may be formed for p-type nanostructure transistors (e.g., p-type metal oxide semiconductor (PMOS) nanostructure transistors), and a second subset of fin structures 204b may be formed for n-type nanostructure transistors (e.g., n-type metal oxide semiconductor (NMOS) nanostructure transistors). Bottoms of the first subset of fin structures 204a may be doped with an n-type dopant (e.g., phosphorous (P) and/or arsenic (As), among other examples) that is opposite of a dopant of the p-type nanostructure transistor. Bottoms of the second subset of fin structures 204b may be doped with p-type dopant (e.g., boron (B) and/or germanium (Ge), among other examples) that is opposite a dopant of the n-type nanostructure transistor. Additionally or alternatively, p-type source/drain regions 210 may be subsequently formed for the p-type nanostructure transistors that include the first subset of fin structures 204a, and n-type source/drain regions 210 may be subsequently formed for the n-type nanostructure transistors that include the second subset of fin structures 204b.

The first subset of fin structures 204a (e.g., PMOS fin structures) and the second subset of fin structures 204b (e.g., NMOS fin structures) may be formed to include similar properties and/or different properties. For example, the first subset of fin structures 204a may be formed to a first height and the second subset of fin structures 204b may be formed to a second height, where the first height and the second height are different heights. As another example, the first subset of fin structures 204a may be formed to a first width and the second subset of fin structures 204b may be formed to a second width, where the first width and the second width are different widths. In the example shown in FIG. 3D, the second width of the second subset of fin structures 204b (e.g., for the NMOS nanostructure transistors) is greater relative to the first width of the first subset of fin structures 204a (e.g., for the PMOS nanostructure transistors). However, other examples are within the scope of the present disclosure.

FIGS. 3E and 3F respectively illustrate a perspective view of the semiconductor device 200 and a cross-sectional view along the line A-A in FIG. 3E. As shown in FIGS. 3E and 3F, a liner 320 and a dielectric layer 322 are formed above the semiconductor substrate 202 and interposing (e.g., in between) the fin structures 204. The deposition tool 102 may deposit the liner 320 and the dielectric layer 322 over the semiconductor substrate 202 and in the trenches between the fin structures 204. The deposition tool 102 may form the dielectric layer 322 such that a height of a top surface of the dielectric layer 322 and a height of a top surface of the nitride layer 314 are approximately a same height.

Alternatively, the deposition tool 102 may form the dielectric layer 322 such that the height of the top surface of the dielectric layer 322 is greater relative to the height of the top surface of the nitride layer 314, as shown in FIGS. 3E and 3F. In this way, the trenches between the fin structures 204 are overfilled with the dielectric layer 322 to ensure the trenches are fully filled with the dielectric layer 322. Subsequently, the planarization tool 110 may perform a planarization or polishing operation (e.g., a CMP operation) to planarize the dielectric layer 322. The nitride layer 314 of the hard mask layer may function as a CMP stop layer in the operation. In other words, the planarization tool 110 planarizes the dielectric layer 322 until reaching the nitride layer 314 of the hard mask layer. Accordingly, a height of top surfaces of the dielectric layer 322 and a height of top surfaces of the nitride layer 314 are approximately equal after the operation.

The deposition tool 102 may deposit the liner 320 using a conformal deposition technique. The deposition tool 102 may deposit the dielectric layer using a CVD technique (e.g., a flowable CVD (FCVD) technique or another CVD technique), a PVD technique, an ALD technique, and/or another deposition technique. In some implementations, after deposition of the dielectric layer 322, the semiconductor device 200 is annealed, for example, to increase the quality of the dielectric layer 322.

The liner 320 and the dielectric layer 322 each includes a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material. In some implementations, the dielectric layer 322 may include a multi-layer structure, for example, having one or more liner layers.

FIGS. 3G and 3H respectively illustrate a perspective view of the semiconductor device 200 and a cross-sectional view along the line A-A in FIG. 3G. As shown in FIGS. 3G and 3H, an etch back operation is performed to remove portions of the liner 320 and portions of the dielectric layer 322 to form the STI regions 206. The etch tool 108 may etch the liner 320 and the dielectric layer 322 in the etch back operation to form the STI regions 206. The etch tool 108 etches the liner 320 and the dielectric layer 322 based on the hard mask layer (e.g., the hard mask layer including the oxide layer 312 and the nitride layer 314). The etch tool 108 etches the liner 320 and the dielectric layer 322 such that the height of the STI regions 206 are less than or approximately a same height as the bottom of the portions 316 of the layer stack 302. Accordingly, the portions 316 of the layer stack 302 extend above the STI regions 206. In some implementations, the liner 320 and the dielectric layer 322 are etched such that the heights of the STI regions 206 are less than heights of top surfaces of the mesa region 318.

In some implementations, the etch tool 108 uses a plasma-based dry etch technique to etch the liner 320 and the dielectric layer 322. Ammonia (NH₃), hydrofluoric acid (HF), and/or another etchant may be used. The plasma-based dry etch technique may result in a reaction between the etchant(s) and the material of the liner 320 and the dielectric layer 322, including:

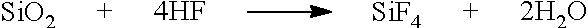

where silicon dioxide (SiO₂) of the liner 320 and the dielectric layer 322 react with hydrofluoric acid to form byproducts including silicon tetrafluoride (SiF₄) and water (H₂O). The silicon tetrafluoride is further broken down by the hydrofluoric acid and ammonia to form an ammonium fluorosilicate ((NH₄)₂SiF₆) byproduct:

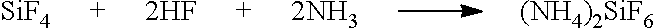

The ammonium fluorosilicate byproduct is removed from a processing chamber of the etch tool 108. After removal of the ammonium fluorosilicate, a post-process temperature in a range of approximately 200 degrees Celsius to approximately 250 degrees Celsius is used to sublimate the ammonium fluorosilicate into constituents of silicon tetrafluoride ammonia and hydrofluoric acid.

As further shown in FIG. 3H, the etch tool 108 may etch the liner 320 and the dielectric layer 322 such that a height of the STI regions 206 between the first subset of fin structures 204a (e.g., for the PMOS nanostructure transistors) is greater relative to a height of the STI regions 206 between the second subset of fin structures 204b (e.g., for the NMOS nanostructure transistors). This primarily occurs due to the greater width the fin structures 204b relative to the width of the fin structures 204a. Moreover, this results in a top surface of an STI region 206 between a fin structure 204a and a fin structure 204b being sloped or slanted (e.g., downward sloped from the fin structure 204a to the fin structure 204b, as shown in the example in FIG. 3H). The etchants used to etch the liner 320 and the dielectric layer 322 first experience physisorption (e.g., a physical bonding to the liner 320 and the dielectric layer 322) as a result of a Van der Waals force between the etchants and the surfaces of the liner 320 and the dielectric layer 322. The etchants become trapped by dipole movement force. The etchants then attach to dangling bonds of the liner 320 and the dielectric layer 322, and chemisorption begins. Here, the chemisorption of the etchant on the surface of the liner 320 and the dielectric layer 322 results in etching of the liner 320 and the dielectric layer 322. The greater width of the trenches between the second subset of fin structures 204b provides a greater surface area for chemisorption to occur, which results in a greater etch rate between the second subset of fin structures 204b. The greater etch rate results in the height of the STI regions 206 between the second subset of fin structures 204b being lesser relative to the height of the STI regions 206 between the first subset of fin structures 204a.

FIGS. 3I and 3J respectively illustrate a perspective view of the semiconductor device 200 and a cross-sectional view along the line A-A in FIG. 3I. As shown in FIGS. 3I and 3J, a cladding layer 324 is formed over the fin structures 204 (e.g., over the top surfaces and over the sidewalls of the fin structures 204) and over the STI regions 206 between the fin structures 204. The cladding layer 324 includes silicon germanium (SiGe) or another material. The deposition tool 102 may deposit the cladding layer 324. In some implementations, the deposition tool 102 deposits a seed layer (e.g., a silicon (Si) seed layer or another type of seed layer) over the fin structures 204 (e.g., over the top surfaces and over the sidewalls of the fin structures 204) and over the STI regions 206 between the fin structures 204. Then, the deposition tool 102 deposits silicon germanium on the seed layer to form the cladding layer 324. The seed layer promotes growth and adhesion of the cladding layer 324.

Deposition of the seed layer may include providing a silicon precursor to a processing chamber of the deposition tool 102 using a carrier gas such as nitrogen (N₂) or hydrogen (H₂), among other examples. In some implementations, a pre-clean operation is performed prior to deposition of the seed layer to reduce the formation of germanium oxide (GeOₓ). The silicon precursor may include disilane (Si₂H₆) or another silicon precursor. The use of disilane may enable formation of a seed layer to a thickness that is in a range of approximately 0.5 nanometers to approximately 1.5 nanometers.

Deposition of the seed layer may be performed at a temperature in a range of approximately 450 degrees Celsius to approximately 500 degrees Celsius (or at a temperature in another range), at a pressure in a range of approximately 30 torr to approximately 100 torr (or at a pressure in another range), and/or for a time duration in a range of approximately 100 seconds to approximately 300 seconds (or for a time duration in another range), among other examples.

Deposition of the silicon germanium of the cladding layer 324 may include forming the cladding layer 324 to include an amorphous texture to promote conformal deposition of the cladding layer 324. The silicon germanium may include a germanium content in a range of approximately 15% germanium to approximately 25% germanium. However, other values for the germanium content are within the scope of the present disclosure. Deposition of the cladding layer 324 may include providing a silicon precursor (e.g., disilane (Si₂H₆) or silicon tetrahydride (SiH₄), among other examples) and a germanium precursor (e.g., germanium tetrahydride (GeH₄) or another germanium precursor) to a processing chamber of the deposition tool 102 using a carrier gas such as nitrogen (N₂) or hydrogen (H₂), among other examples. Deposition of the cladding layer 324 may be performed at a temperature in a range of approximately 500 degrees Celsius to approximately 550 degrees Celsius (or at a temperature in another range) and/or at a pressure in a range of approximately 5 torr to approximately 20 torr (or at a pressure in another range).

FIGS. 3K and 3L respectively illustrate a perspective view of the semiconductor device 200 and a cross-sectional view along the line A-A in FIG. 3K. As shown in FIGS. 3K and 3L, an etch back operation is performed to etch the cladding layer 324 to form cladding sidewall layers 326. The etch tool 108 may etch the cladding layer 324 using a plasma-based dry etch technique or another etch technique. The etch tool 108 may perform the etch back operation to remove portions of the cladding layer 324 from the tops of the fin structures 204 and from the tops of the STI regions 206.

In some implementations, the etch tool 108 uses a fluorine-based etchant to etch the cladding layer 324. The fluorine-based etchant may include sulfur hexafluoride (SF₆), fluoromethane (CH₃F₃), and/or another fluorine-based etchant. Other reactants and/or carriers such as methane (CH₄), hydrogen (H2), argon (Ar), and/or helium (He) may be used in the etch back operation. In some implementations, the etch back operation is performed using a plasma bias in a range of approximately 500 volts to approximately 2000 volts. However, other values for the plasma bias are within the scope of the present disclosure.

In some implementations, removing portions of the cladding layer 324 from the tops of the STI regions 206 includes removing (e.g., selectively etching) one or more footings. In some implementations, the one or more footings are formed over of the STI regions 206 from the cladding layer 324 due to a quality of the liner 320 within the STI regions 206. In some implementations, the one or more footings are formed over the STI regions 206 during conformal deposition of the cladding layer 324.

FIGS. 3M and 3N respectively illustrate a perspective view of the semiconductor device 200 and a cross-sectional view along the line A-A in FIG. 3M. As shown in FIGS. 3M and 3N, the hard mask layer (including the oxide layer 312 and the nitride layer 314) and the capping layer 310 are removed to expose the hard mask layer 308. In some implementations, the capping layer 310, the oxide layer 312, and the nitride layer 314 are removed using an etch operation (e.g., performed by the etch tool 108), a planarization technique (e.g., performed by the planarization tool 110), and/or another semiconductor processing technique.

FIGS. 3O and 3P respectively illustrate a perspective view of the semiconductor device 200 and a cross-sectional view along the line A-A in FIG. 3O. As shown in FIGS. 3O and 3P, a liner 328 and a dielectric layer 330 are formed above the semiconductor substrate 202 and interposing (e.g., in between) the fin structures 204. The deposition tool 102 may deposit the liner 328 and the dielectric layer 330 over the semiconductor substrate 202 and between the cladding sidewall layers 326 in the trenches between the fin structures 204. The deposition tool 102 may form the dielectric layer 330 such that a height of a top surface of the dielectric layer 330 and a height of a top surface of the hard mask layer 308 are approximately a same height.

Alternatively, the deposition tool 102 may form the dielectric layer 330 such that the height of the top surface of the dielectric layer 330 is greater relative to the height of the top surface of the hard mask layer 308, as shown in FIGS. 3O and 3P. In this way, the trenches between the fin structures 204 are overfilled with the dielectric layer 330 to ensure the trenches are fully filled with the dielectric layer 330. Subsequently, the planarization tool 110 may perform a planarization or polishing operation (e.g., a CMP operation) to planarize the dielectric layer 330.

The deposition tool 102 may deposit the liner 328 using a conformal deposition technique. The deposition tool 102 may deposit the dielectric layer 330 using a CVD technique (e.g., a flowable CVD (FCVD) technique or another CVD technique), a PVD technique, an ALD technique, and/or another deposition technique. In some implementations, after deposition of the dielectric layer 330, the semiconductor device 200 is annealed, for example, to increase the quality of the dielectric layer 330.

The liner 328 and the dielectric layer 330 each includes a dielectric material such as a silicon oxide (SiOₓ), a silicon nitride (SiₓN_{y}), a silicon oxynitride (SiON), a silicon carbon nitride (SiCN), fluoride-doped silicate glass (FSG), a low-k dielectric material, and/or another suitable insulating material. In some implementations, the dielectric layer 330 may include a multi-layer structure, for example, having one or more liner layers.

FIGS. 3Q and 3R respectively illustrate a perspective view of the semiconductor device 200 and a cross-sectional view along the line A-A in FIG. 3Q. As shown in FIGS. 3Q and 3R, an etch back operation is performed to remove portions of the dielectric layer 330. The etch tool 108 may etch the dielectric layer 330 in the etch back operation to reduce a height of a top surface of the dielectric layer 330. In particular, the etch tool 108 etches the dielectric layer 330 such that the height of portions of the dielectric layer 330 between the fin structures 204 is less than the height of the top surface of the hard mask layer 308. In some implementations, the etch tool 108 etches the dielectric layer 330 such that the height of portions of the dielectric layer 330 between the fin structures 204 is approximately equal to a height of top surfaces of the top-most of the second layers 306 of the portions 316.

FIGS. 3S and 3T respectively illustrate a perspective view of the semiconductor device 200 and a cross-sectional view along the line A-A in FIG. 3S. As shown in FIGS. 3S and 3T, a high dielectric constant (high-k) layer 332 is deposited over the portions of the dielectric layer 330 between the fin structures 204. The deposition tool 102 may deposit a high-k material such as a hafnium oxide (HfOₓ) and/or another high-k dielectric material to form the high-k layer 332 using a CVD technique, a PVD technique, an ALD technique, and/or another deposition technique. The combination of the portions of the dielectric layer 330 between the fin structures 204 and the high-k layer 332 between the fin structures 204 is referred to as a hybrid fin structure 334 (or dummy fin structure). In some implementations, the planarization tool 110 may perform a planarization operation to planarize the high-k layer 332 such that a height of a top surface of the high-k layer 332 and the height of the hard mask layer 308 are approximately equal.

Subsequently, and as shown in FIGS. 3S and 3T, the hard mask layer 308 is removed. Removal of the hard mask layer 308 may include using an etch technique (e.g., a plasma etch technique, a wet chemical etch technique, and/or another type of etch technique) or another removal technique.

FIG. 3U illustrates a perspective view of the semiconductor device 200. As shown in FIG. 3U, dummy gate structures 336 (also referred to as dummy gate stacks) are formed over the fin structures 204 and over the hybrid fin structures 334. The dummy gate structures 336 are sacrificial structures that are to be replaced by replacement gate structures (or replacement gate stacks) at a subsequent processing stage for the semiconductor device 200. Portions of the fin structures 204 underlying the dummy gate structures 336 may be referred to as channel regions. The dummy gate structures 336 may also define source/drain (S/D) regions of the fin structures 204, such as the regions of the fin structures 204 adjacent and on opposing sides of the channel regions.

A dummy gate structure 336 may include a gate electrode layer 338, a hard mask layer 340 over and/or on the gate electrode layer 338, and spacer layers 342 on opposing sides of the gate electrode layer 338 and on opposing sides of the hard mask layer 340. The dummy gate structures 336 may be formed on a gate dielectric layer 344 between the fin structures 204 and the dummy gate structures 336, and between the hybrid fin structures 334 and the dummy gate structures 336. The gate electrode layer 338 includes polycrystalline silicon (polysilicon or PO) or another material. The hard mask layer 340 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The spacer layers 342 include a silicon oxycarbide (SiOC), a nitrogen free SiOC, or another suitable material. The gate dielectric layer 344 may include a silicon oxide (e.g., SiOₓ such as SiO₂), a silicon nitride (e.g., SiₓN_{y} such as Si₃N₄), a high-K dielectric material and/or another suitable material.

The layers of the dummy gate structures 336 may be formed using various semiconductor processing techniques such as deposition (e.g., by the deposition tool 102), patterning (e.g., by the exposure tool 104 and the developer tool 106), and/or etching (e.g., by the etch tool 108), among other examples. Examples include CVD, PVD, ALD, thermal oxidation, e-beam evaporation, photolithography, e-beam lithography, photoresist coating (e.g., spin-on coating), soft baking, mask aligning, exposure, post-exposure baking, photoresist developing, rinsing, drying (e.g., spin-drying and/or hard baking), dry etching (e.g., reactive ion etching), and/or wet etching, among other examples.

In some implementations, the gate dielectric layer 344 is conformally deposited on the semiconductor device 200 and then selectively removed from portions of the semiconductor device 200 (e.g., the source/drain areas). The gate electrode layer 338 is then deposited onto the remaining portions of the gate dielectric layer 344. The hard mask layers 340 are then deposited onto the gate electrode layers 338. The spacer layers 342 may be conformally deposited in a similar manner as the gate dielectric layer 344. In some implementations, the spacer layers 342 include a plurality of types of spacer layers. For example, the spacer layers 342 may include a seal spacer layer that is formed on the sidewalls of the dummy gate structures 336 and a bulk spacer layer that is formed on the seal spacer layer. The seal spacer layer and the bulk spacer layer may be formed of similar materials or different materials. In some implementations, the bulk spacer layer is formed without plasma surface treatment that is used for the seal spacer layer. In some implementations, the bulk spacer layer is formed to a greater thickness relative to the thickness of the seal spacer layer.

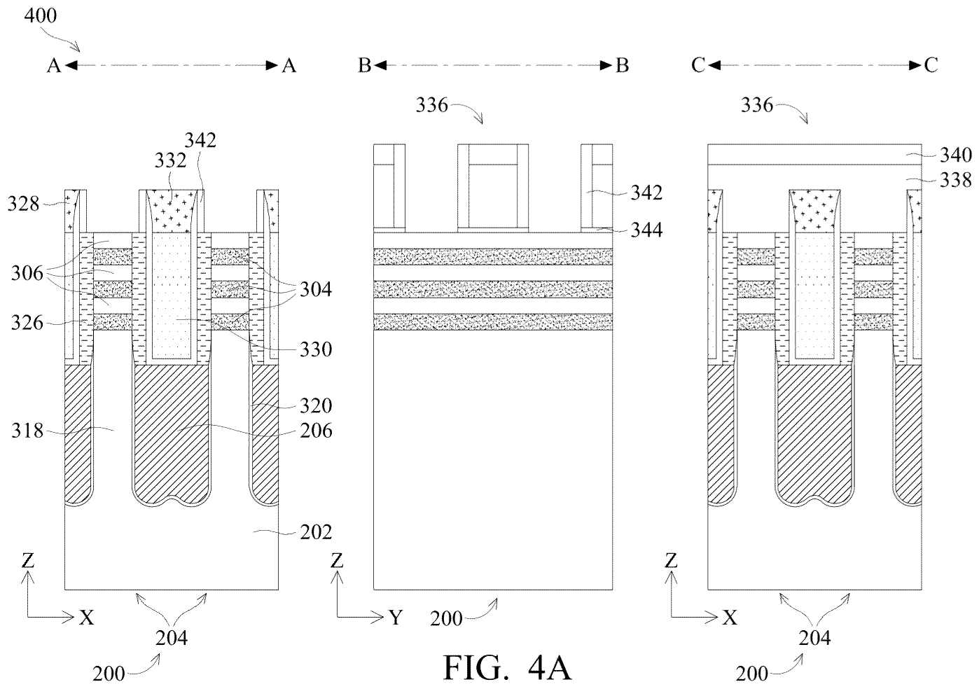

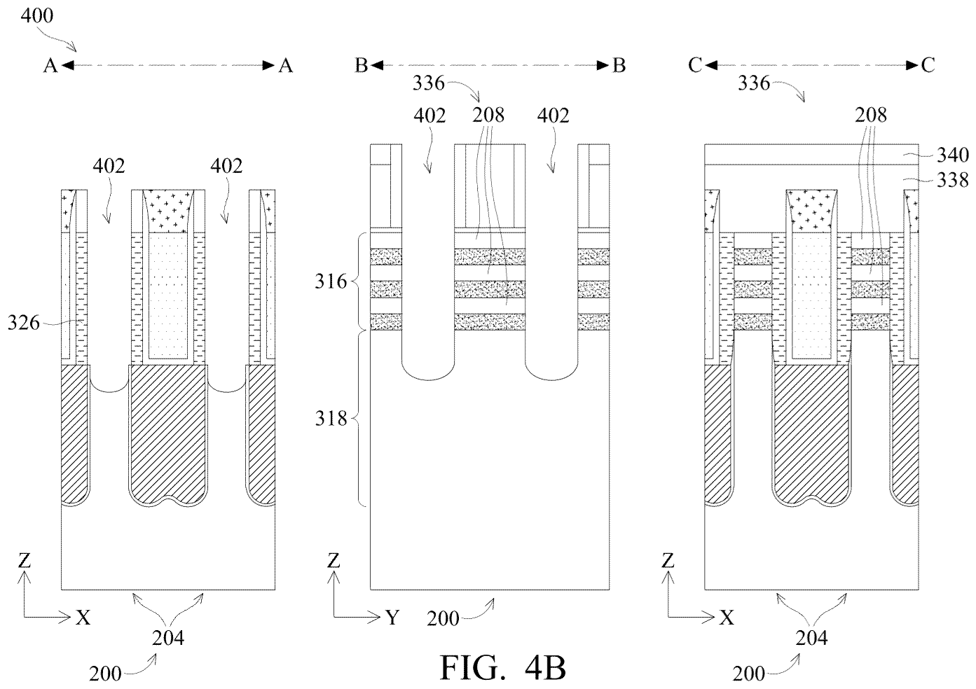

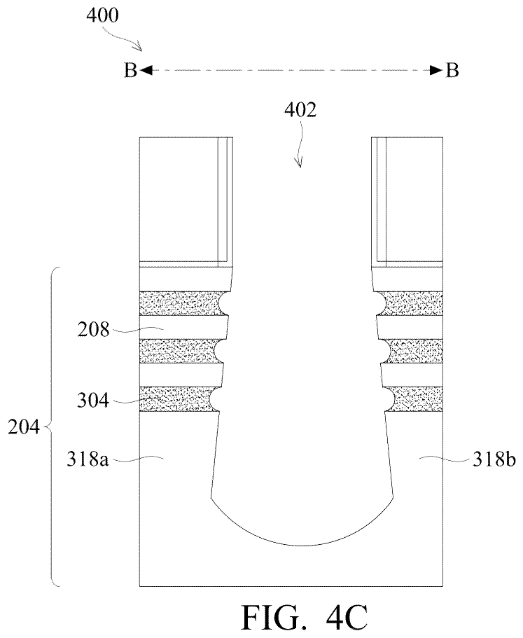

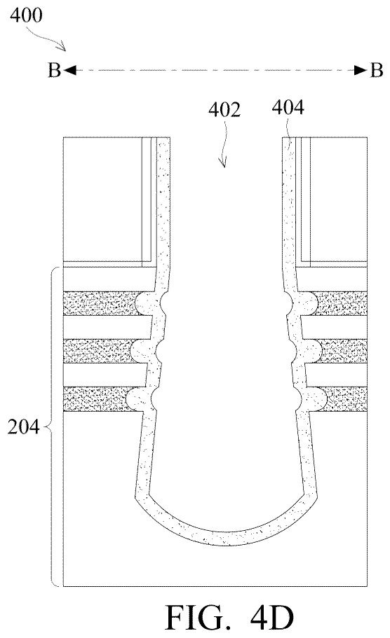

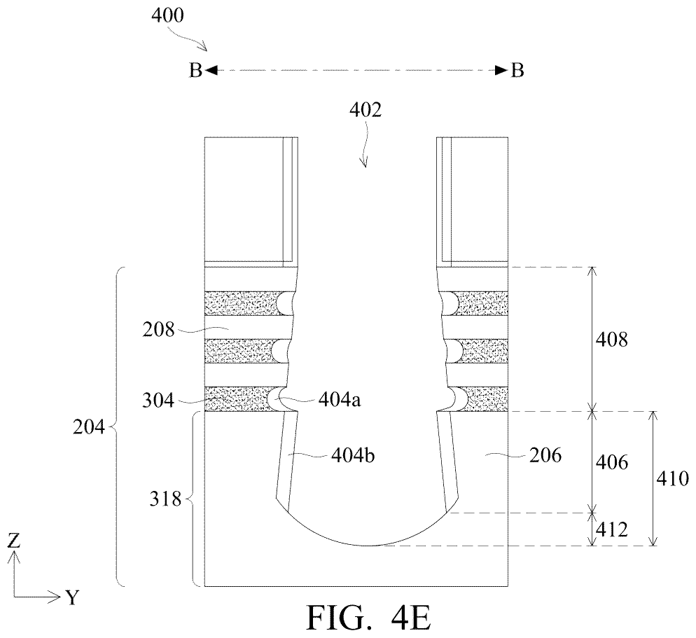

FIG. 3U further illustrates reference cross-sections that are used in later figures, including FIGS. 4A-4D. Cross-section A-A is in an x-z plane (referred to as a y-cut) across the fin structures 204 and the hybrid fin structures 334 in source/drain areas of the semiconductor device 200. Cross-section B-B is in a y-z plane (referred to as an x-cut) perpendicular to the cross-section A-A, and is across the dummy gate structures 336 in the source/drain areas of the semiconductor device 200. Cross-section C-C is in the x-z plane parallel to the cross-section A-A and perpendicular to the cross-section B-B, and is along a dummy gate structures 336. Subsequent figures refer to these reference cross-sections for clarity. In some figures, some reference numbers of components or features illustrated therein may be omitted to avoid obscuring other components or features for case of depicting the figures.

As indicated above, the number and arrangement of operations and devices shown in FIGS. 3A-3U are provided as one or more examples. In practice, there may be additional operations and devices, fewer operations and devices, different operations and devices, or differently arranged operations and devices than those shown in FIGS. 3A-3U.

FIGS. 4A-4E are diagrams of an example implementation 400 described herein. FIGS. 4A-4E are illustrated from the perspective of the cross-sectional plane B-B in FIG. 3U, and the perspective of the cross-sectional plane C-C in FIG. 3U. Operations shown in the example implementation 400 may be performed in a different order than shown in FIGS. 4A-4E. The example implementation 400 includes an example of forming the semiconductor device 200 or a portion thereof (e.g., an example of forming a recess including inner spacer layers for the source/drain region 210 of the semiconductor device 200).

As shown in FIG. 4A, the dummy gate structures 336 are formed above the fin structures 204. As shown in the cross-sectional plane C-C in FIG. 4A, portions of the gate dielectric layer 344 and portions of the gate electrode layers 338 are formed in recesses above the fin structures 204 that are formed as a result of the removal of the hard mask layer 308. The formation of the dummy gate structures 336 is described in connection with FIG. 3U.

As shown in the cross-sectional plane A-A and cross-sectional plane B-B in FIG. 4B, source/drain recesses 402 are formed in the portions 316 of the fin structure 204 in an etch operation. The source/drain recesses 402 are formed to provide spaces in which source/drain regions 210 are to be formed on opposing sides of the dummy gate structures 336. The etch operation may be performed by the etch tool 108 and may be referred to a strained source/drain (SSD) etch operation. In some implementations, the etch operation includes a plasma etch technique, a wet chemical etch technique, and/or another type of etch technique.

As further shown in the cross-sectional plane A-A and cross-sectional plane B-B in FIG. 4B, the source/drain recesses 402 may further be formed adjacent to the mesa regions 318 of the fin structure 204. In these implementations, the source/drain recesses 402 penetrate into a well portion (e.g., a p-well, an n-well) of the fin structure 204. In implementations in which the semiconductor substrate 202 includes a silicon (Si) material having a <100> orientation, <111> faces are formed at bottoms of the source/drain recesses 402. In some implementations, a wet etching using tetramethylammonium hydroxide (TMAH) and/or a chemical dry etching using hydrochloric acid (HCl) are employed form the source/drain recess 402.

As shown in the cross-sectional plane B-B and the cross-sectional plane C-C in FIG. 4B, portions of the first layers 304 and portions of the second layers 306 of the layer stack 302 remain under the dummy gate structures 336 after the etch operation to form the source/drain recesses 402. The portions of the second layers 306 under the dummy gate structures 336 form the channels 208 of the nanostructure transistors of the semiconductor device 200.

FIG. 4C shows an example implementation of the source/drain recess 402. As shown in the cross-sectional plane B-B of FIG. 4C, a bottom portion of the source/drain recess 402 includes a tapered region extending into the fin structure 204 between mesa regions (e.g., mesa region 318a and mesa region 318b) of the fin structure 204. As an example, the etch tool 108 may form the source/drain recess 402 including the tapered region using a recipe including a particular flow profile and/or concentration of etchants, among other examples. The recipe may be configured such that that the etchants are in contact with surfaces at or near lower regions of the source/drain recess 402 for a longer time duration than surfaces at or near upper regions of the source/drain recess 402, which results in more etching at the bottom of the source/drain recess 402 relative to the top of the source/drain recess 402 to cause the tapered region.

The tapered region may extend below a top surface of the mesa region 318. A width of the tapered region may be wider at the bottom and narrower at the top. The tapered region may extend between a top surface of a top-most nanostructure channel 208 and at a transition between sidewalls of the source/drain recess 402. In some implementations, angles of the tapered region (e.g., angles relative to a vertical sidewall of the source/drain recess or angles relative to a transition between the sidewalls of the source/drain recess 402) may be symmetrical.

As shown in the cross-sectional plane B-B in FIG. 4D, an inner spacer layer 404 is deposited in the source/drain recess 402. As an example, the deposition tool 102 may deposit the inner spacer layer 404 to form inner spacers in cavities in the first layers 304 between the channels 208 to provide increased isolation between the gate structures 212 (e.g., the replacement gate structures) and the source/drain regions 210 that are to be formed in the source/drain recesses 402 for reduced parasitic capacitance. The inner spacer layer 404 includes a silicon nitride (SiₓN_{y}), a silicon oxide (SiOₓ), a silicon oxynitride (SiON), a silicon oxycarbide (SiOC), a silicon carbon nitride (SiCN), a silicon oxycarbonitride (SiOCN), and/or another dielectric material. The inner spacer layer 404 and the spacer layers 342 may be formed of the same material or of different materials.

In some implementations, and as shown in cross-sectional plane B-B of FIG. 4E, portions of the inner spacer layer 404 are removed. As an example, the etch tool 108 may perform a wet etch or a dry etch operation that removes material along a <100> lattice plane of the inner spacer layer 404 (e.g., along a <100> lattice plane of the SiGe material) and retains material along a <110> lattice plane of the inner spacer layer 404 (e.g., along a <110> lattice plane of the SiGe material).

In implementations where the first layers 304 are silicon germanium (SiGe) and the nanostructure channels 208 are silicon (Si), the etch tool 108 may selectively etch the first layers 304 using a wet etchant such as, a mixed solution including hydrogen peroxide (H₂O₂), acetic acid (CH₃COOH), and/or hydrogen fluoride (HF), followed by a cleaning with water (H₂O). The mixed solution and the water may be provided into the source/drain recesses 402 to etch the first layers 304 from the source/drain recesses 402. In some implementations, the etching by the mixed solution and cleaning by water is repeated approximately 10 times to approximately 20 times. The etching time with the mixed solution is in a range from about 1 minute to about 2 minutes in some implementations. The mixed solution may be used at a temperature in a range of approximately 60° Celsius to approximately 90° Celsius. However, other values for the parameters of the etch operation are within the scope of the present disclosure. The first layers 304 are laterally etched to form the cavities in the ends of the first layers 304. The inner spacer layers 404 are then formed on the ends of the first layers 304 in the cavities. In some implementations, a conformal layer is deposited (e.g., by the deposition tool 102) in the source/drain recesses 402, and the etch tool 108 removes excess material of the conformal layer to form the inner spacer layers 404.

As a result, inner spacers 404a (e.g., portions of the inner spacer layer 404) may remain on ends of the first layers 304 and sidewall layers 404b (e.g., other portions of the inner spacer layer 404, or deep inner spacer sidewalls) may remain on portions of opposing sidewalls of the source/drain recess 402 that correspond to sidewalls of opposing mesa regions 318 of the fin structure 204. Moreover, the sidewall layers 404b may remain on portions of opposing sidewalls of the source/drain recess 402 due to the tapered shape of the source/drain recess 402. In particular, the directionally of the etch may result in the inner spacer layer 404 on the sidewalls of the source/drain recess 402 at the top of the source/drain recess 402 being etched faster than the inner spacer layer 404 on the sidewalls of the source/drain recess 402 at the bottom of the source/drain recess 402 due to the width of the source/drain recess 402 at the bottom of the source/drain recess 402 being greater relative to the width of the source/drain recess 402 at the top of the source/drain recess 402. Moreover, the directionally of the etch may result in the inner spacer layer 404 on the bottom surface of the source/drain recess 402 being etched faster than the inner spacer layer 404 on the sidewalls of the source/drain recess 402 at the bottom of the source/drain recess 402, effective to create sidewall layers 404b.

The source/drain recess 402, the inner spacers 404a, the sidewall layers 404b, and the fin structure 204 may include one or more dimensional properties. For example, a sidewall layer 404b may be formed to a depth 406 such that no portion of an adjacent mesa region 318 is exposed between the top of the sidewall layer 404b and the bottom-most inner spacer 404a next to the sidewall layer 404b. This reduces the likelihood of dopant leakage/migration between the sidewall layer 404b and the bottom-most inner spacer 404a. In some implementations, the depth 406 of the sidewall layer 404b (e.g., from a bottom of the bottom-most inner spacer 404a to a bottom of the sidewall layer 404b along the sidewall of the adjacent mesa region 318) is included in a range of approximately 2 nanometers to approximately 20 nanometers. In some implementations, the depth 406 corresponds to a depth below a top-most portion of the shallow trench isolation region 206. If the depth 406 is less than approximately 2 nanometers, the sidewall layer 404b may be ineffective in reducing the likelihood of dopants of the source/drain region 210 (e.g., dopants from a subsequent deposition of epitaxial materials in the source/drain recess 402) from migrating into the mesa regions 318. If the depth is greater than approximately 20 nanometers, residual material of the inner spacer layer 404 may remain on the ends of the nanostructure channels 208, which may reduce device performance of the semiconductor device 200. However, other values and ranges for the depth 406 are within the scope of the present disclosure.

Additionally, or alternatively, the fin structure 204 may extend to a height 408 above the mesa region 318 (e.g., above a bottom surface of a bottom-most inner spacer 404a and/or a bottom surface of a bottom-most first layer 304). The height 408 may be included in a range of approximately 30 nanometers to approximately 80 nanometers. If the height 408 is less than approximately 30 nanometers, a drive current of the semiconductor device 200 may be lower than a targeted drive current due to a reduction in a number of nanosheets in the semiconductor device 200. If the height is greater than approximately 80 nanometers, the fin structure 204 may experience mechanical bending issues and an increased amount of manufacturing defects. However, other values and ranges for the height 408 are within the scope of the present disclosure.

Additionally, or alternatively, a depth 410 of the source/drain recess 402 below the fin structure 204 (e.g., below a bottom surface of the bottom-most inner spacer 404a) may be included in a range of approximately 5 nanometers to approximately 50 nanometers. If the depth 410 is less than approximately 5 nanometers, a buffer region in a bottom portion of the source/drain recess 402 may be ineffective in reducing the likelihood of dopants of the source/drain region 210 from migrating into the mesa regions 318. If the depth 410 is greater than approximately 50 nanometers, deposition costs of one or more layers of epitaxial materials within the source/drain recess 402 would increase. However, other values and ranges for the depth 410 are within the scope of the present disclosure.

Additionally, or alternatively, the depth 406 (e.g., a second depth) may be lesser relative to the depth 410 (e.g., a first depth) by a distance 412. The distance 412 may be included in a range of approximately 5 nanometers to approximately 15 nanometers. If the distance 412 is less than approximately 5 nanometers, a bottom surface of the source/drain recess 402 may be flat and induce defects into the semiconductor device 200. If the distance 412 is greater than 15 nanometers, epitaxial materials within the source/drain recess 402 might extend beyond or beneath the sidewall layers 404b and a migration of dopants (e.g., dopants from epitaxial materials within the source/drain recess 402) to the mesa region 318 might occur. However, other values and ranges for the distance 412 are within the scope of the present disclosure.

As indicated above, the number and arrangement of operations and devices shown in FIGS. 4A-4E are provided as one or more examples. In practice, there may be additional operations and devices, fewer operations and devices, different operations and devices, or differently arranged operations and devices than those shown in FIGS. 4A-4E.

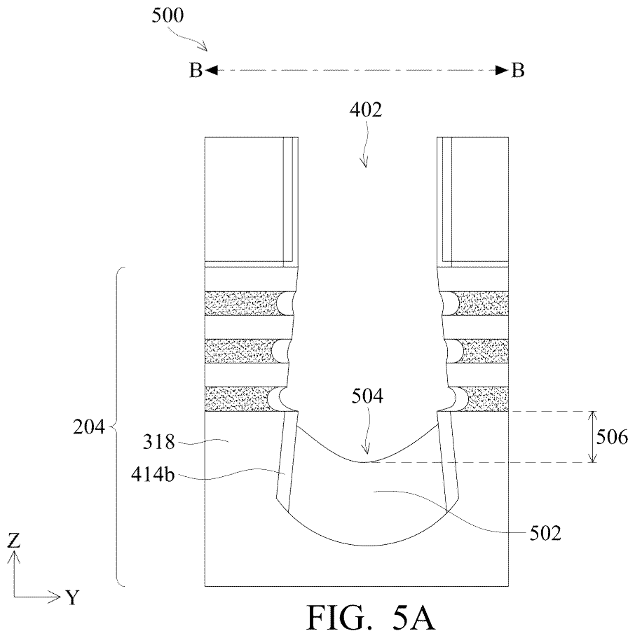

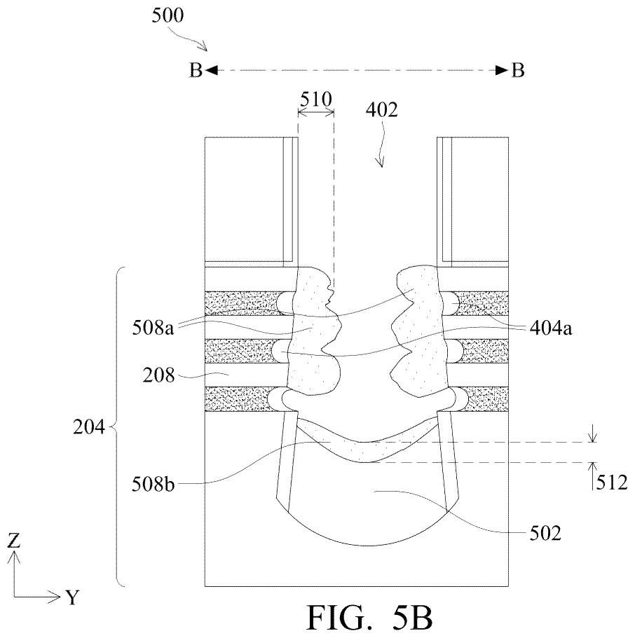

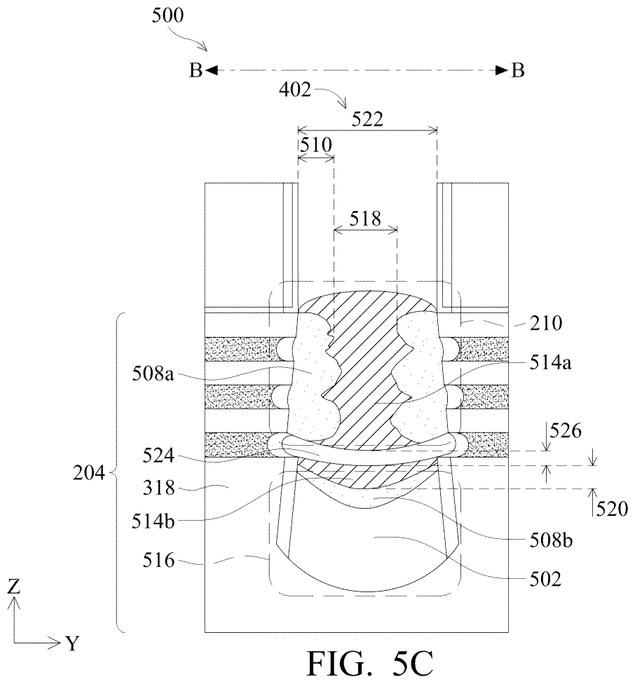

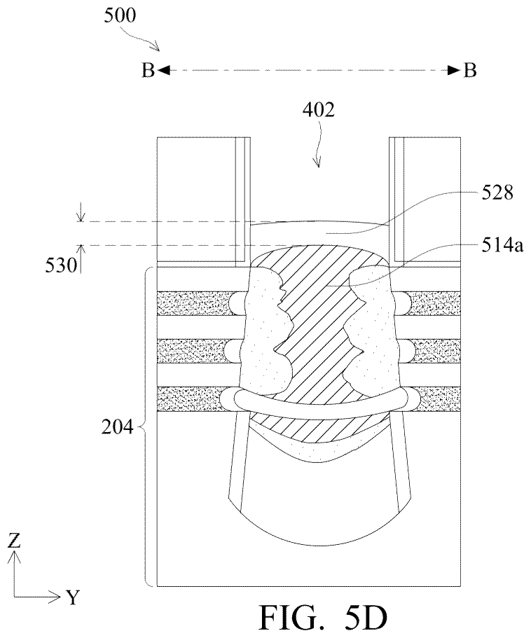

FIGS. 5A-5D are diagrams of an example implementation 500 described herein. FIGS. 5A-5D are illustrated from the perspective of the cross-sectional plane B-B in FIG. 3U. Operations shown in the example implementation 500 may be performed in a different order than shown in FIGS. 5A-5D. The example implementation 500 includes an example of forming the semiconductor device 200 or a portion thereof (e.g., an example of forming a dielectric region between epitaxial layers in the source/drain region 210 and a buffer region of the semiconductor device 200).

As shown in cross-sectional plane B-B of FIG. 5A, an epitaxial layer 502 is deposited at the bottom of the source/drain recess 402. As an example, the deposition tool 102 of FIG. 1 may deposit the epitaxial layer 502 using a CVD or a PVD process, among other examples. The epitaxial layer 502 (e.g., a buffer layer) may include an un-doped material such as a silicon material (Si), a silicon germanium (SiGe) material, a silicon nitride (SiN) material, or a high dielectric constant (high-k) dielectric material (e.g., a hafnium oxide (HfOₓ) and/or another high-k dielectric material), among other examples.

The epitaxial layer 502 may include a concave top surface 504. The concave top surface 504 (e.g., a bottom-most portion of the concave top surface 504) may be at a depth 506 relative to a top surface of sidewall layer 404b, a bottom surface of a bottom-most inner spacer 404a, and/or a top surface of the mesa region 318. The depth 506 may be included in a range of approximately 5 nanometers to approximately 20 nanometers. If the depth 506 is less than approximately 5 nanometers, a flatness of the concave top surface 504 would reduce amounts of epitaxial layers in the source/drain region 210 (e.g., additional epitaxial layers subsequently deposited above the epitaxial layer 502 as part of the source/drain region 210). If the depth is greater than approximately 20 nanometers, epitaxial layers of the source/drain region 210 may extend to a depth below the sidewall layers 404b and cause a migration of dopants into the mesa region 318. However, other values and ranges for the depth 506 are within the scope of the present disclosure. The height of the sides of the concave top surface 504 may be approximately equal to the height of the top surfaces of the sidewall layers 404b or may be less than the height of the top surfaces of the sidewall layers 404b, as shown in the example in FIG. 5A.

Cross-sectional plane B-B of FIG. 5B shows an epitaxial layer 508 (e.g., an epitaxial layer 508 including one or more portions 508a and a portion 508b) deposited in the source/drain recess 402. For example, the deposition tool 102 of FIG. 1 may deposit the epitaxial layer 508 using a CVD technique, an ALD technique, a PVD technique, and/or another deposition technique.

For a PMOS nanostructure transistor, the epitaxial layer 508 may include a silicon germanium material doped with boron (SiGeB). The germanium (Ge) concentration in the epitaxial layer 508 may be in a range of approximately 20% germanium to approximately 40% germanium. The doping concentration of boron may be in a range of approximately 1×10²⁰ atoms per cubic centimeter to approximately 8×10²⁰ atoms per cubic centimeter. However, other combinations of materials, dopants, and ranges for the doping concentration for epitaxial layer 508 of the PMOS nanostructure transistor are within the scope of the present disclosure.

For an NMOS nanostructure transistor, the epitaxial layer 508 may include a silicon material doped with arsenic (SiAs). In such cases, the doping concentration of arsenic may be in a range of approximately 5×10²⁰ atoms per cubic centimeter to approximately 1×10²¹ atoms per cubic centimeter. Additionally, or alternatively, the epitaxial layer 508 may include a silicon material doped with phosphorous (SiP). In such cases, the doping concentration of phosphorous may be included in a range of approximately 1×10²⁰ atoms per cubic centimeter to approximately 8×10²¹ atoms per cubic centimeter. However, other combinations of materials, dopants, and ranges for the doping concentration for the epitaxial layer 508 of the NMOS nanostructure transistor are within the scope of the present disclosure.

As shown in FIG. 5B, a portion 508a of the epitaxial layer 508 may be formed over and/or on ends of the nanostructure channels 208 of a fin structure 204, and over and/or on the inner spacers 404a. A portion 508a of the epitaxial layer may merge across (e.g., may be continuous across) the inner spacers 404a to reduce a likelihood of dopant leakage into the nanostructure channels 208. Moreover, the portions 508a may be formed to fully cover the ends of each of the nanostructure channels 208 to reduce the likelihood of dopant leakage into the nanostructure channels 208.

Further, and as shown in FIG. 5B, a portion 508b of the epitaxial layer 508 may be formed over and/or on the epitaxial layer 502 and between the sidewall layers 404b. In some implementations, a growth rate of the epitaxial layer 508 may be dependent on an underlying material or structure. For example, and as shown, a growth rate of the portion 508b over the epitaxial layer 502 (e.g., a dielectric material) may be lesser relative to a growth rate of the portion 508a over the nanostructure channels 208 (e.g., a silicon material) and/or the inner spacers 404a (e.g., a silicon germanium (SiGe) material). In such cases, a width 510 of the portion 508a may greater relative to a thickness 512 of the portion 508b. For example, the width 510 may be in a range of approximately 5 nanometers to approximately 10 nanometers, and the thickness 512 may be in a range of approximately 3 nanometers to approximately 10 nanometers.

If the width 510 is less than approximately 5 nanometers, a performance of the semiconductor device 200 (e.g., short channel effects in the fin structure 204 caused by increased likelihood of dopant leakage) may be decreased. If the width 510 is greater than approximately 10 nanometers, availability of space for another epitaxial material adjacent to the portion 508b may be reduced (e.g., portions 508a on opposing sides of the source/drain recess 402 may become connected, which may prevent the formation of another, higher doped, epitaxial material between the portions 508a). However, other values and ranges for the width 510 are within the scope of the present disclosure.

If the thickness 512 of the portion 508b is less than approximately 3 nanometers, the corresponding width 510 of the portion 508a may be undersized (e.g., less than 5 nanometers) and cause a decrease in performance of the semiconductor device 200 (e.g., likelihood of short channel effects in the fin structure 204 may be increased). If the thickness 512 is greater than approximately 10 nanometers, availability of space for another epitaxial layer above the portion 508b may be reduced. However, other values and ranges for the thickness 512 are within the scope of the present disclosure.

Cross-sectional plane B-B of FIG. 5C shows an epitaxial layer 514 (e.g., a portion 514a and a portion 514b) deposited in the source/drain recess 402. For example, the deposition tool 102 of FIG. 1 may deposit the epitaxial layer 514 using a CVD technique, an ALD technique, a PVD technique, and/or another deposition technique.

The portion 508a and the portion 514a may combine to form the source/drain region 210. The epitaxial layer 502, the portion 508b, and the portion 514b may combine to form a buffer region 516 that is adjacent to the mesa region 318.

For a PMOS nanostructure transistor, the epitaxial layer 514 may include a silicon germanium material doped with boron (SiGeB). In such a case, the germanium (Ge) concentration in the epitaxial layer 514 may be in a range of approximately 40% germanium to approximately 60% germanium. The doping concentration of boron may be in a range of approximately 8×10²⁰ atoms per cubic centimeter to approximately 3×10²¹ atoms per cubic centimeter. However, other combinations of materials, dopants, and ranges for the doping concentration for epitaxial layer 514 of the PMOS nanostructure transistor are within the scope of the present disclosure.

For an NMOS nanostructure transistor, the epitaxial layer 514 may include a silicon material doped with phosphorous (SiP). In such a case, the doping concentration of phosphorous may be in a range of approximately 8×10²⁰ atoms per cubic centimeter to approximately 3×10²¹ atoms per cubic centimeter. However, other combinations of materials, dopants, and ranges for the doping concentration for the epitaxial layer 514 of the NMOS nanostructure transistor are within the scope of the present disclosure.

A width 518 of the portion 514a adjacent to the portion 508a may be included in a range of approximately 5 nanometers to approximately 15 nanometers. If the width 518 is less than approximately 5 nanometers, a decrease in the amount of the epitaxial layer 514 (e.g., the portion 514a) may reduce a performance of the source/drain region 210. If the width 518 is greater than approximately 15 nanometers, the corresponding width 510 of the portion 508a may be undersized (e.g., less than 5 nanometers), which may result in a decrease in performance of the semiconductor device 200 (e.g., short channel effects in the fin structure 204).

A thickness 520 of the portion 514b over the portion 508b may be included in a range of approximately 1 nanometer to approximately 10 nanometers. If the thickness 520 is less than approximately 1 nanometer, a corresponding width of the portion 514a (e.g., the width 518) may be undersized and reduce a performance of the source/drain region 210. If the thickness 520 is greater than approximately 10 nanometers, available space for a dielectric region between the source/drain region 210 and the buffer region 516 may be reduced. However, other values and ranges for the thickness 520 are within the scope of the present disclosure. In some implementations, the portion 514b is omitted from the semiconductor device 200.

In some implementations, a ratio of the width 510 to a width 522 of the source/drain region (e.g., the width 522 at the top of the source/drain recess 402) is included in a range of approximately 1:10 to approximately 2:5. If the ratio is less than approximately 1:10 (e.g., less than 10%), short channel effects within the semiconductor device (e.g., nanostructure transistor) may increase. If the ratio is greater than approximately 2:5 (e.g., greater than 40%), a volume of the portion 514a may be reduced to reduce performance of the source/drain region 210. However, other values and ranges for the ratio are within the scope of the present disclosure.

As shown in FIG. 5C, the formation of the epitaxial layer 514 creates a dielectric region 524 (e.g., an air gap or a region including a dielectric gas, among other examples) between a top surface of the buffer region 516 (e.g., a top surface of the portion 514b) and a bottom surface of the source/drain region 210 (e.g., a bottom surface of the portion 508a and a bottom surface of the portion 514a). The dielectric region 524 may prevent a migration of dopants from the source/drain region 210 (e.g., dopants such as boron, germanium, arsenic, or phosphorous, among other examples) through the buffer region 516 and into the mesa regions 318. By preventing the migration of the dopants, a likelihood of electron tunneling within the mesa regions 318 is reduced (e.g., a likelihood of leakage within the semiconductor device 200 is reduced). In some implementations, a bottom surface of the dielectric region 524 extends below a top surface of the mesa regions 318. In some implementations, a top surface of the dielectric region extends above a top surface of the mesa regions.

The dielectric region 524 may include a thickness 526. The thickness 526 may be included in a range of approximately 3 nanometers to approximately 10 nanometers. If the thickness 526 is less than approximately 3 nanometers, the portion 514b might merge with the portion 514a and/or the portion 508a, which may increase the likelihood of dopant leakage. If the thickness 526 is greater than approximately 10 nanometers, a volume of the portion 514a may be reduced to reduce a performance of the source/drain region 210. However, other values and ranges for the thickness 526 are within the scope of the present disclosure.

Cross-sectional plane B-B of FIG. 5D shows a capping layer 528 deposited over the portion 514a. For example, the deposition tool 102 of FIG. 1 may deposit the capping layer 528 using a CVD process or a PVD process.

For a PMOS nanostructure transistor, the capping layer 528 may include a silicon germanium material doped with boron (SiGeB). In such a case, the germanium (Ge) concentration in the capping layer 528 may be in a range of approximately 45% germanium to approximately 55% germanium. The doping concentration of boron may be in a range of approximately 1×10²¹ atoms per cubic centimeter to approximately 2×10²¹ atoms per cubic centimeter. However, other combinations of materials, dopants, and ranges for the doping concentration for the capping layer 528 of the PMOS transistor are within the scope of the present disclosure.

For an NMOS nanostructure transistor, the capping layer 528 may include a silicon material doped with phosphorous (SiP). In such a case, the doping concentration of phosphorous may be in a range of approximately 1×10²¹ atoms per cubic centimeter to approximately 2×10²¹ atoms per cubic centimeter. However, other combinations of materials, dopants, and ranges for the doping concentration for the capping layer 528 of the NMOS nanostructure transistor are within the scope of the present disclosure.

The capping layer 528 may include a thickness 530. The thickness 530 may be included in a range of approximately 2 nanometers to approximately 15 nanometers. If the thickness 530 is less than approximately 2 nanometers, the capping layer 528 will not protect the source/drain region 210 from additional semiconductor manufacturing processes. If the thickness 530 is greater than approximately 15 nanometers, merging issues with subsequent structures (e.g., contact vias) might arise. However, other values and ranges for the thickness 530 are within the scope of the present disclosure.

As indicated above, the number and arrangement of operations and devices shown in FIGS. 5A-5D are provided as one or more examples. In practice, there may be additional operations and devices, fewer operations and devices, different operations and devices, or differently arranged operations and devices than those shown in FIGS. 5A-5D.

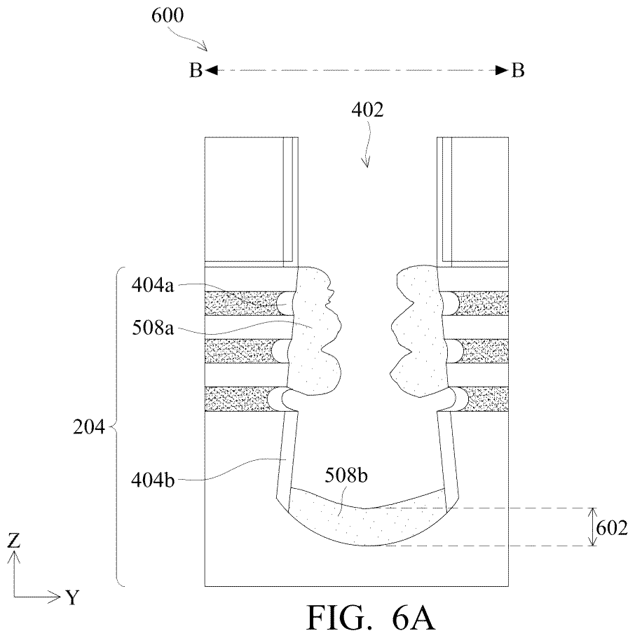

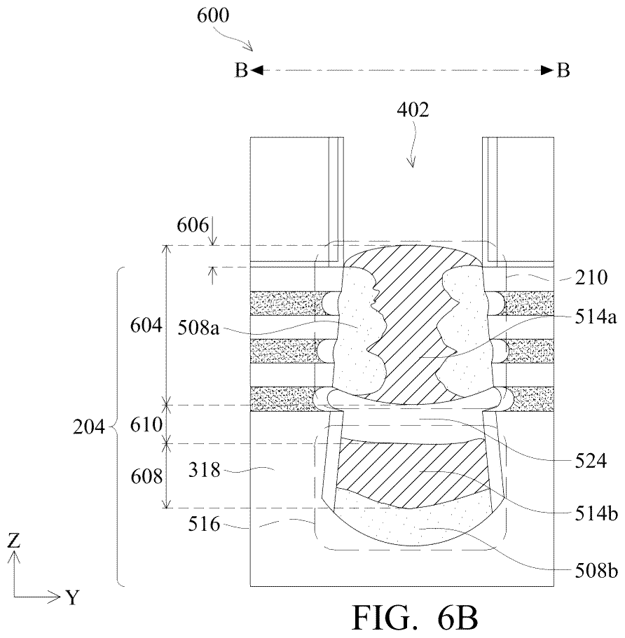

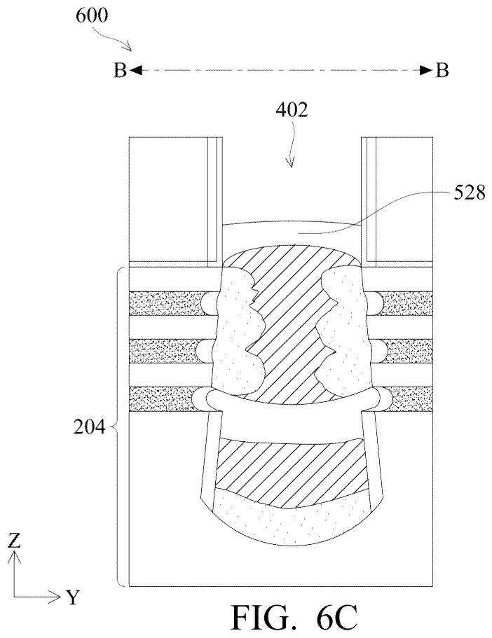

FIGS. 6A-6C are diagrams of an example implementation 600 described herein. FIGS. 6A-6C are illustrated from the perspective of the cross-sectional plane B-B in FIG. 3U. Operations shown in the example implementation 600 may be performed in a different order than shown in FIGS. 6A-6C. The example implementation 600 includes an example of forming the semiconductor device 200 or a portion thereof (e.g., an example of forming a dielectric region between epitaxial layers in the source/drain region 210 and a buffer region of the semiconductor device 200).

The example implementation 600 is an alternative implementation to the example implementation 500. In particular, formation of the epitaxial layer 502 is omitted in example implementation 600. This reduces process complexity of forming the semiconductor device 200. The portion 508b is formed to provide sufficient dopant leakage/migration protection in combination with the sidewall layers 404b.

As shown in cross-sectional plane B-B of FIG. 6A, an epitaxial layer 508 (e.g., including the portions 508a and the portion 508b) are deposited in the source/drain recess 402. As an example, the deposition tool 102 of FIG. 1 may deposit the epitaxial layer 508 using a CVD or a PVD process, among other examples. In some implementations, the epitaxial layer 508 corresponds to a first epitaxial layer and the portions 508a corresponds to a first portion of the first epitaxial layer.

As shown in FIG. 6A, the portion 508b of the epitaxial layer 508 is formed on the bottom surface of the source/drain recess 402 (e.g., on the bottom-most surface of the tapered region of the source/drain recess 402) and between the sidewall layers 404b. The portion 508b may include a concave top surface. In some implementations, the portion 508b includes a thickness 602 to eliminate gaps between the portion 508b and the sidewall layers 404b (which would otherwise provide dopant leakage paths). The thickness 602 may be included in a range of approximately 5 nanometers to approximately 20 nanometers. If the thickness 602 is less than approximately 5 nanometers, a corresponding width of the portion 508a may be undersized, which may result in dopant leakage. If the thickness 602 is greater than approximately 20 nanometers, too much material may be deposited for the portions 508a (e.g., portions 508a on opposing sides of the source/drain recess 402 may become connected, which may prevent the formation of another, higher doped, epitaxial material between the portions 508a). However, other values and ranges for the thickness 602 are within the scope of the present disclosure.

Cross section B-B of FIG. 6B shows the epitaxial layer 514 (e.g., the portion 514a and the portion 514b) deposited in the source/drain recess 402. For example, the deposition tool 102 of FIG. 1 may deposit the epitaxial layer 514 using a CVD technique, an ALD technique, a PVD technique, and/or another deposition technique. The portion 508a and the portion 514a may combine to form the source/drain region 210. The portion 508b and the portion 514b may combine to form a buffer region 516 that is adjacent to the mesa region 318.

The portion 514a may include a thickness 604. The thickness 604 may be included in a range of approximately 30 nanometers to approximately 50 nanometers. If the thickness 604 is less than approximately 30 nanometers, a volume of the portion 514a may be undersized and cause a decrease in a performance of the source/drain region 210. If the thickness 604 is greater than approximately 50 nanometers, a likelihood of shorting between the source/drain region 210 and a gate structure 212 may be increased. However, other values and ranges for the thickness 604 are within the scope of the present disclosure.

The portion 514a may extend to a height 606 above the fin structure. The height 606 may be included in a range of approximately 1 nanometer to approximately 5 nanometers. If the height 606 is less than approximately 1 nanometer, a volume of the portion 514a may be undersized and cause a decrease in a performance of the source/drain region 210. If the height 606 is greater than approximately 5 nanometers, a likelihood of shorting between the source/drain region 210 and a gate structure 212 may be increased. However, other values and ranges for the height 606 are within the scope of the present disclosure.

The portion 514b may have a thickness 608. The thickness 608 may be included in a range of approximately 5 nanometers to approximately 20 nanometers. If the thickness 608 is less than approximately 5 nanometers, a corresponding thickness and/or volume of the portion 514a may be undersized which may result in a decrease in a performance of the source/drain region 210. If the thickness 608 is greater than approximately 20 nanometers, the portion 514b might merge with the portion 514a and/or the portion 508a. However, other values and ranges for the thickness 608 are within the scope of the present disclosure.

As shown in FIG. 6B, the formation of the epitaxial layer 514 creates a dielectric region 524 (e.g., an air gap or a region filled with a dielectric gas, among other examples) between a top surface of the buffer region 516 (e.g., a top surface of the portion 514b) and a bottom surface of the source/drain region 210 (e.g., a bottom surface of the portion 508a and a bottom surface of the portion 514a).

The dielectric region 524 may include a thickness 610. The thickness 610 may be included in a range of approximately 5 nanometers to approximately 30 nanometers. If the thickness 604 is less than approximately 5 nanometers, the portion 514b might merge with the portion 514a and/or the portion 508a. If the thickness is greater than approximately 30 nanometers, a volume of the portion 514a may be reduced (which may reduce a performance of the source/drain region 210). However, other values and ranges for the thickness 610 are within the scope of the present disclosure.

Cross-sectional plane B-B of FIG. 6C shows a capping layer 528 deposited over the portion 514a. For example, the deposition tool 102 of FIG. 1 may deposit the capping layer 528 using a CVD process or a PVD process. The capping layer 528 may include a material and a thickness, as described with regard to FIG. 5D.

As indicated above, the number and arrangement of operations and devices shown in FIGS. 6A-6C are provided as one or more examples. In practice, there may be additional operations and devices, fewer operations and devices, different operations and devices, or differently arranged operations and devices than those shown in FIGS. 6A-6C.

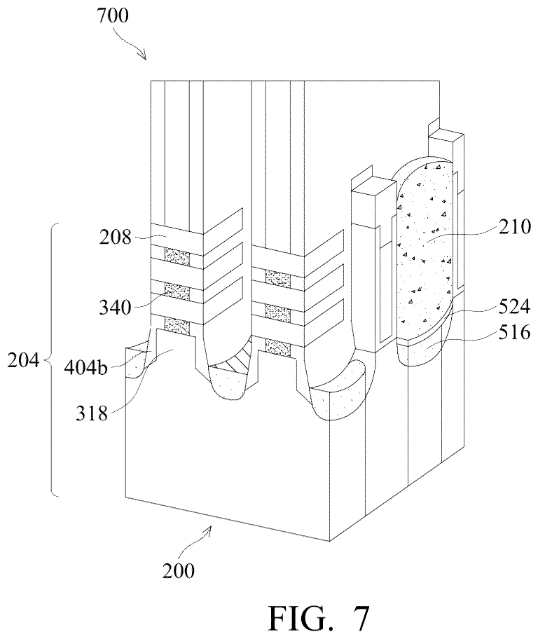

FIG. 7 is a diagram of an example implementation 700 described herein. The implementation 700 includes a perspective view of the semiconductor device 200 in a partially completed state (e.g., after formation of features as described in connection with one or more operations of FIGS. 3A-3U, 4A-4E, 5A-5D, and 6A-6C).

As shown in FIG. 7, one or more fin structures 204 include nanosheets (e.g., the first layers 304 and the nanostructure channels 208) above the mesa region 318. FIG. 7 further shows the source/drain region 210 and the buffer region 516. The dielectric region 524 is between a bottom surface of the source/drain region 210 and a top surface of the buffer region 516.

FIG. 7 further shows the sidewall layers 404b extending into the mesa region 318. The sidewall layers 404b extend into the mesa regions 318 and are adjacent to the buffer region 516.

As indicated above, the number and arrangement of devices shown in FIG. 7 is provided as one or more examples. In practice, there may be additional devices, fewer devices, different devices, or differently arranged devices than those shown in FIG. 7.

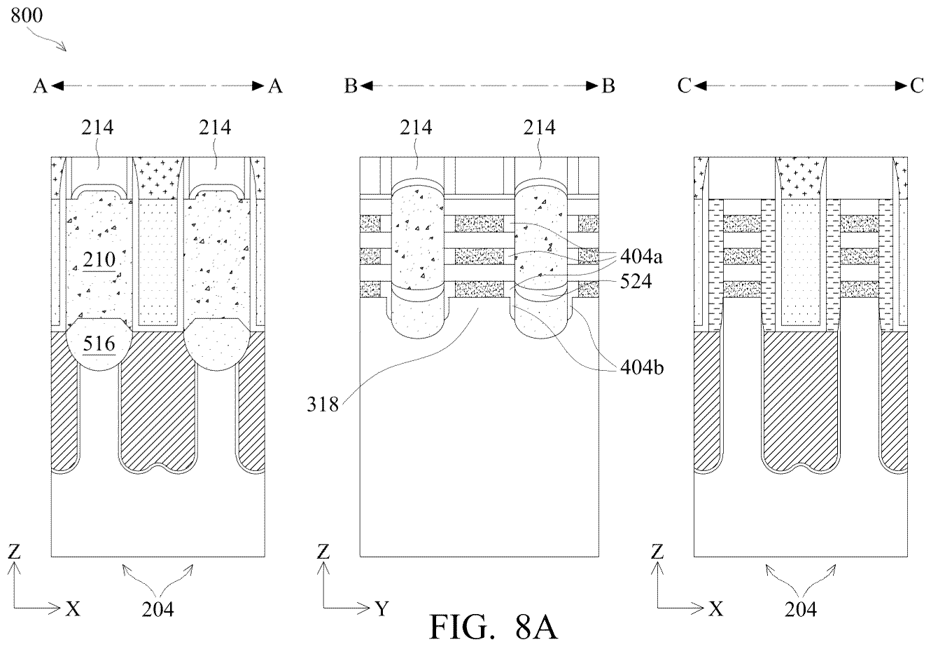

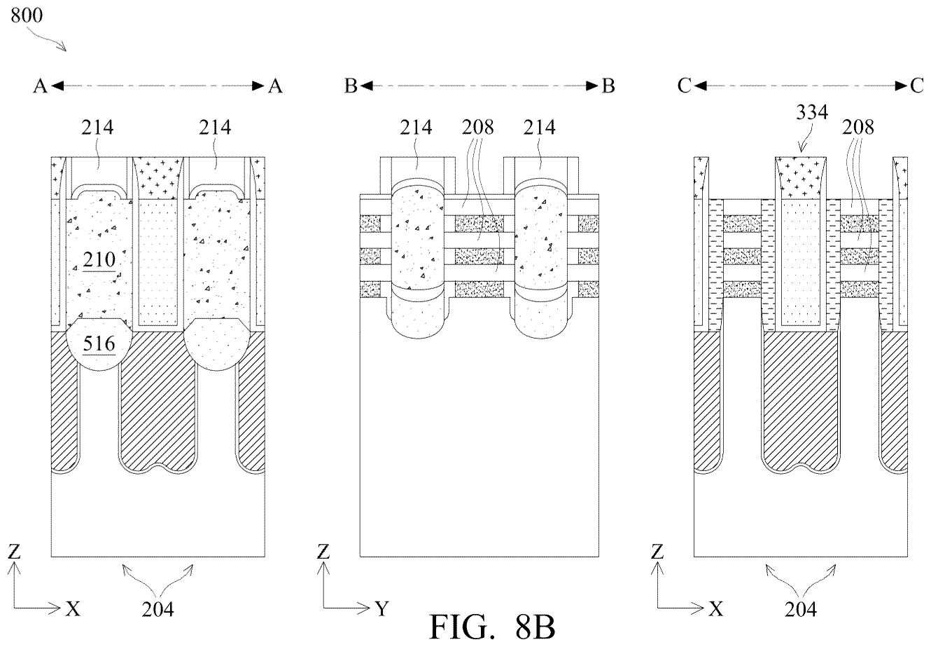

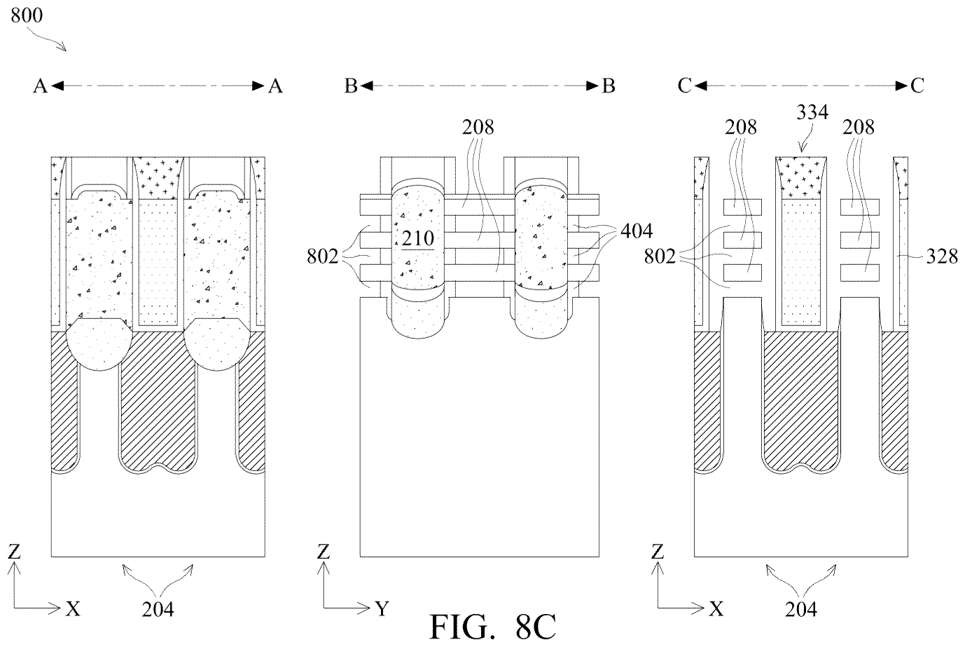

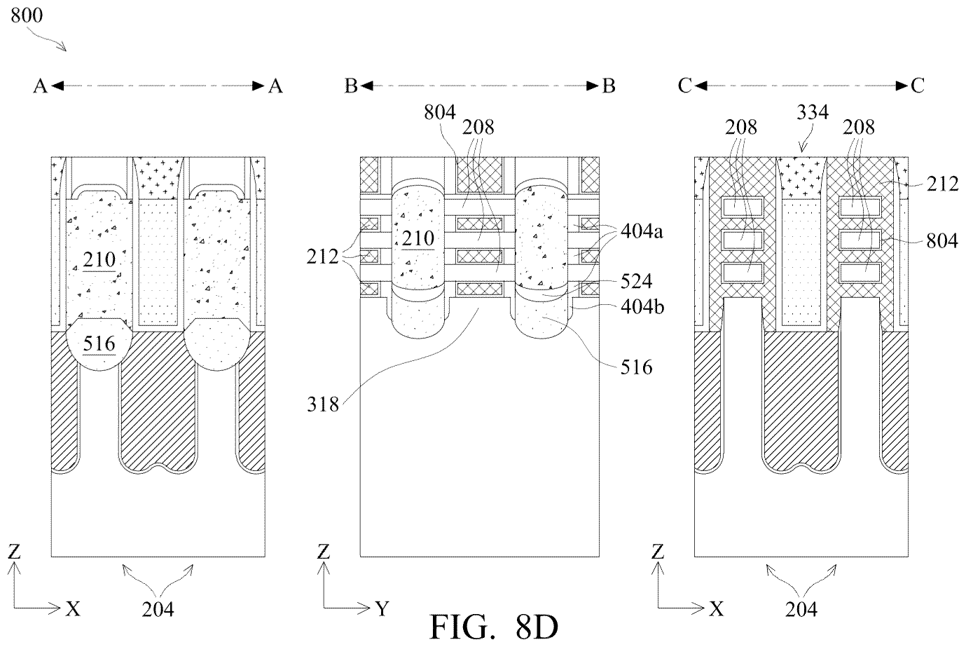

FIGS. 8A-8D are diagrams of an example implementation 800 described herein. The implementation 800 includes an example of a replacement gate process (RPG) for replacing the dummy gate structures 336 with the gate structures 212 (e.g., the replacement gate structures) of the semiconductor device 200. FIGS. 8A-8D are illustrated from a plurality of perspectives illustrated in FIG. 3U, including the perspective of the cross-sectional plane A-A in FIG. 3U, the perspective of the cross-sectional plane B-B in FIG. 3U, and the perspective of the cross-sectional plane C-C in FIG. 3U. In some implementations, the operations described in connection with the example implementation 800 are performed after the operations described in connection with FIGS. 3A-3U, 4A-4E, 5A-5D, and 6A-6C.

As shown in the cross-sectional plane A-A and the cross-sectional plane B-B in FIG. 8A, the dielectric layer 214 is formed over the source/drain regions 210 and the buffer region 516. The dielectric layer 214 fills in areas between the dummy gate structures 336, between the hybrid fin structures 334, and over the source/drain regions 210. The dielectric layer 214 is formed to reduce the likelihood of and/or prevent damage to the source/drain regions 210 during the replacement gate process. The dielectric layer 214 may be referred to as an interlayer dielectric (ILD) zero (ILD0) layer or another ILD layer. Cross-sectional plane B-B shows the dielectric region 524.

The cross-sectional plane B-B of FIG. 8A shows the dielectric region 524. The cross-sectional plane B-B of FIG. 8A also shows the inner spacers 404a and the sidewall layers 404b extending into the mesa region 318.

In some implementations, a contact etch stop layer (CESL) is conformally deposited (e.g., by the deposition tool 102) over the source/drain regions 210, over the dummy gate structures 336, and on the spacer layers 342 prior to formation of the dielectric layer 214. The dielectric layer 214 is then formed on the CESL. The CESL may provide a mechanism to stop an etch process when forming contacts or vias for the source/drain regions 210. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As shown in the cross-sectional plane B-B and the cross-sectional plane C-C in FIG. 8B, the replacement gate operation is performed (e.g., by one or more of the semiconductor processing tools 102-112) to remove the dummy gate structures 336 from the semiconductor device 200. The removal of the dummy gate structures 336 leaves behind openings (or recesses) between the dielectric layer 214 over the source/drain regions 210, and between the hybrid fin structures 334 over the fin structures 204. The dummy gate structures 336 may be removed in one or more etch operations. Such etch operations may include a plasma etch technique, a wet chemical etch technique, and/or another type of etch technique.

As shown in the cross-sectional plane B-B and the cross-sectional plane C-C in FIG. 8C, a nanostructure release operation is performed to remove the first layers 304 (e.g., the silicon germanium layers). This results in openings 802 between the channels 208 (e.g., the areas around the channels 208). The nanostructure release operation may include the etch tool 108 performing an etch operation to remove the first layer 304 based on a difference in etch selectivity between the material of the first layers 304 and the material of the channels 208, and between the material of the first layers 304 and the material of the inner spacer layers 404. The inner spacer layers 404 may function as etch stop layers in the etch operation to protect the source/drain regions 210 from being etched. As further shown in FIG. 8C, the cladding sidewall layers 326 are removed in the nanostructure release operation. This provides access to the areas around the nanostructure channels 208, which enable replacement gate structures (e.g., the gate structures 212) to be formed fully around the nanostructure channels 208.

As shown in the cross-sectional plan B-B and the cross-sectional plane C-C in FIG. 8D, the replacement gate operation continues where deposition tool 102 and/or the plating tool 112 forms the gate structures (e.g., replacement gate structures) 212 in the openings 802 between the source/drain regions 210 and between the hybrid fin structures 334. In particular, the gate structures 212 fill the areas between and around the channels 208 that were previously occupied by the first layers 304 and the cladding sidewall layers 326 such that the gate structures 212 surround the channels 208. The gate structures 212 may include metal gate structures. A conformal high-k dielectric liner 804 may be deposited onto the channels 208 and on sidewalls prior to formation of the gate structures 212. The gate structures 212 may include additional layers such as an interfacial layer, a work function tuning layer, and/or a metal electrode structure, among other examples.

As further shown in the cross-sectional plane C-C in FIG. 8D, the removal of the cladding layer 324 from the tops of the STI regions 206 to prevent the cladding sidewall layers 326 from including footings under the hybrid fin structures 334 between adjacent fin structures 204 enables the gate structures 212 to be formed such that the gate structure 212 does not include a footing under the hybrid fin structures 334. In other words, since the gate structures 212 are formed in the areas that were previously occupied by the cladding sidewall layers 326, the absence of a footing under the hybrid fin structures 334 for the cladding sidewall layers 326 also results in an absence of a footing under the hybrid fin structures 334 for the gate structures 212. This reduces and/or prevents shorting between the gate structures 212 and the source/drain regions 210 under the hybrid fin structures 334.

The cross-sectional plane C-C in FIG. 8D further shows the inner spacers 404a and the sidewall layers 404b extending into the mesa region 318. The sidewall layers 404b are adjacent to the buffer region 516. The dielectric region 524 is also shown in FIG. 8D, between the buffer region 516 and the source/drain region 210.

As indicated above, the number and arrangement of operations and devices shown in FIGS. 8A-8D are provided as one or more examples. In practice, there may be additional operations and devices, fewer operations and devices, different operations and devices, or differently arranged operations and devices than those shown in FIGS. 8A-8D.

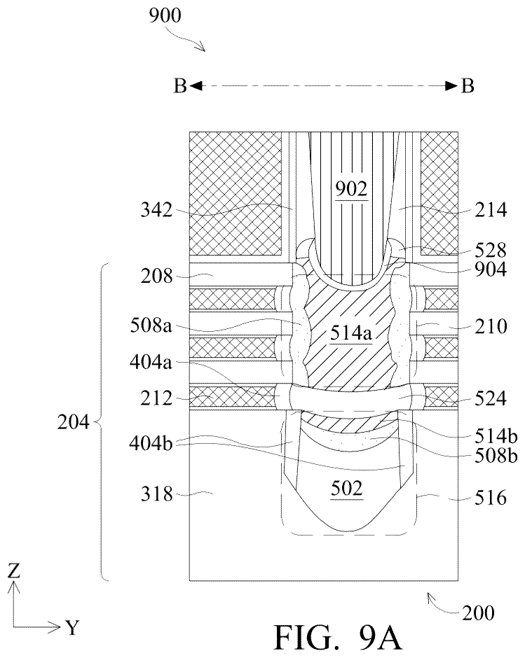

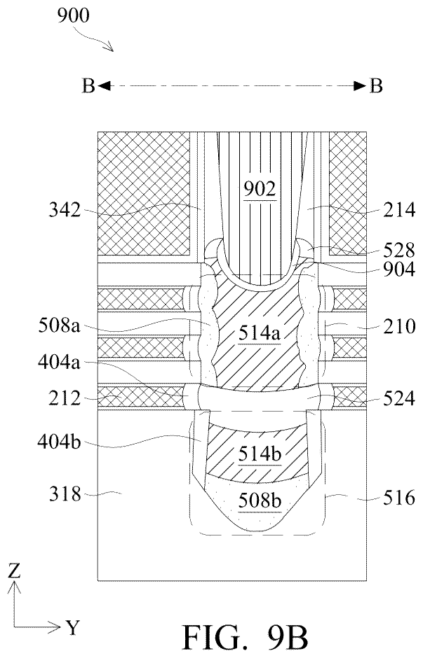

FIGS. 9A and 9B are diagrams of an example implementation 900 described herein. FIGS. 9A and 9B are illustrated from the perspective of the cross-sectional plane B-B in FIG. 3U and show the sidewall layers 404b and the dielectric region 524 (e.g., the air gap) in relation to other structures and/or layers of the semiconductor device 200 after the replacement gate process described in connection with FIGS. 8A-8D.

FIG. 9A includes an example implementation in which the semiconductor device 200 includes the epitaxial layer 502. As shown in the cross-sectional view B-B of FIG. 9A, the semiconductor device 200 includes the fin structure 204. The fin structure 204 includes the mesa region 318 and a plurality of nanostructure channels (e.g., the channels 208, formed from the second layers 306) above the mesa region 318. In FIG. 9A, the buffer region 516 is adjacent to the mesa region 318. The source/drain region 210 is above the buffer region 516 and adjacent to the plurality of nanostructure channels.

In FIG. 9A, the buffer region 516 includes the epitaxial layer 502 (e.g., a first epitaxial layer), the portion 508b (e.g., a first portion of a second epitaxial layer) over the epitaxial layer 502, and the portion 514b (e.g., a first portion of a third epitaxial layer). The dielectric region 524 is between the top surface of the buffer region 516 and the bottom surface of the source/drain region 210. The dielectric region 524 is configured to reduce a likelihood of dopants of the source/drain region 210 from migrating into the mesa region 318 to reduce a likelihood of a leakage within the semiconductor device 200.

The source/drain region 210 includes the portion 508a (e.g., a second portion of the second epitaxial layer) over the inner spacers 404a and the portion 514a (e.g., a second portion of the third epitaxial layer) adjacent to the portion 508a.

FIG. 9A further shows the gate structure 212, the dielectric layer 214 (e.g., formed over the source/drain region 210 during the replacement gate operation), and the spacer layers 342 remaining after removal of the dummy gate structure 336.

In FIG. 9A, a source/drain contact 902 (referred to as an MD) is formed to the source/drain region 210 through the dielectric layer 214. To form the source/drain contact 902, a recess is formed through the dielectric layer 214 and to the source/drain region 210. In some implementations, the recess is formed in a portion of the source/drain region 210 such that the source/drain contact 902 extends into a portion of the source/drain region 210, as shown in the example in FIG. 9A.

In some implementations, a pattern in a photoresist layer is used to form the opening. In these implementations, the deposition tool 102 forms the photoresist layer on the dielectric layer 214 and on the gate structures 212. The exposure tool 104 exposes the photoresist layer to a radiation source to pattern the photoresist layer. The developer tool 106 develops and removes portions of the photoresist layer to expose the pattern. The etch tool 108 etches into the dielectric layer 214 to form the recess. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recess based on a pattern.

A metal silicide layer 904 is formed on the source/drain region 210 in the recess prior to forming the source/drain contact 902. The deposition tool 102 may form the metal silicide layer 904 to decrease contact resistance between the source/drain region 210 and the source/drain contact 902. Moreover, the metal silicide layer 904 may protect the source/drain region 210 from oxidization and/or other contamination. The metal silicide layer 904 includes a titanium silicide (TiSiₓ) layer or another type of metal silicide layer.

The source/drain contact 902 is then formed in the recess and on the metal silicide layer 904 over the source/drain region 210. The deposition tool 102 and/or the plating tool 112 deposits the source/drain contact 902 using a CVD technique, a PVD technique, an ALD technique, an electroplating technique, another deposition technique described above in connection with FIG. 1, and/or a deposition technique other than as described above in connection with FIG. 1. The source/drain contact 902 includes ruthenium (Ru), tungsten (W), cobalt (Co), and/or another metal.

FIG. 9B illustrates an alternative implementation in which the epitaxial layer 502 is omitted from the semiconductor device 200. As shown in the cross-sectional view B-B of FIG. 9B, the buffer region 516 includes the portion 508b (e.g., a portion of a first epitaxial layer) and the portion 514b (e.g., a portion of a second epitaxial layer) over the portion 508b. The dielectric region 524 is between the top surface of the buffer region 516 and the bottom surface of the source/drain region 210. The dielectric region 524 is configured to reduce a likelihood of dopants of the source/drain region 210 from migrating into the mesa region 318 to reduce a likelihood of a leakage within the semiconductor device 200. The source/drain region 210 includes the portion 508a (e.g., a second portion of the first epitaxial layer) over the inner spacers 404a and the portion 514a (e.g., a second portion of the second epitaxial layer) adjacent to the portion 508a.

As indicated above, the number and arrangement of materials and/or layers shown in FIGS. 9A and 9B are provided as one or more examples. In practice, there may be additional devices, fewer devices, different devices, or differently devices than those shown in FIGS. 9A and 9B.

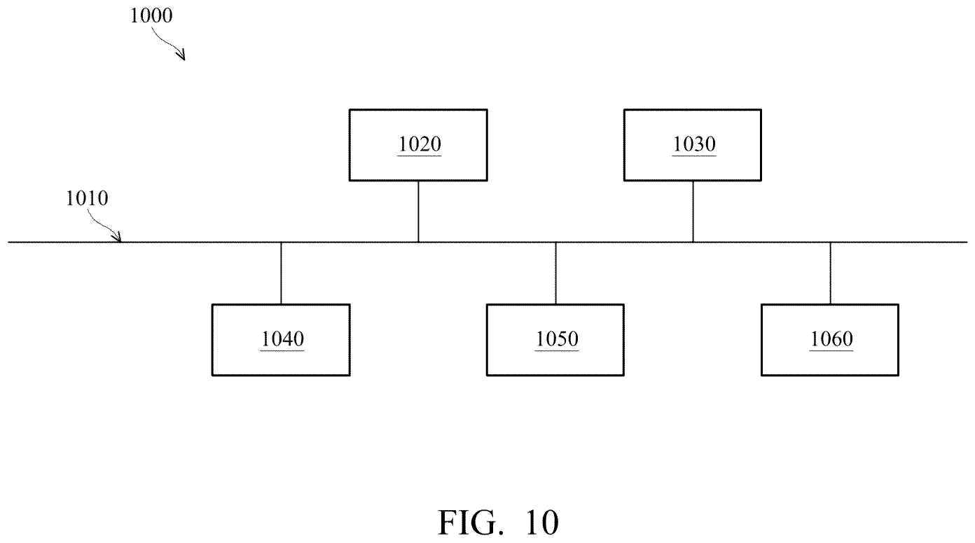

FIG. 10 is a diagram of example components of one or more devices 1000 described herein. In some implementations, one or more of the semiconductor processing devices 102-112 and/or the wafer/die transport tool 114 may include one or more devices 1000 and/or one or more components of device 1000. As shown in FIG. 10, device 1000 may include a bus 1010, a processor 1020, a memory 1030, an input component 1040, an output component 1050, and a communication component 1060.

Bus 1010 includes one or more components that enable wired and/or wireless communication among the components of device 1000. Bus 1010 may couple together two or more components of FIG. 10, such as via operative coupling, communicative coupling, electronic coupling, and/or electric coupling. Processor 1020 includes a central processing unit, a graphics processing unit, a microprocessor, a controller, a microcontroller, a digital signal processor, a field-programmable gate array, an application-specific integrated circuit, and/or another type of processing component. Processor 1020 is implemented in hardware, firmware, or a combination of hardware and software. In some implementations, processor 1020 includes one or more processors capable of being programmed to perform one or more operations or processes described elsewhere herein.

Memory 1030 includes volatile and/or nonvolatile memory. For example, memory 1030 may include random access memory (RAM), read only memory (ROM), a hard disk drive, and/or another type of memory (e.g., a flash memory, a magnetic memory, and/or an optical memory). Memory 1030 may include internal memory (e.g., RAM, ROM, or a hard disk drive) and/or removable memory (e.g., removable via a universal serial bus connection). Memory 1030 may be a non-transitory computer-readable medium. Memory 1030 stores information, instructions, and/or software (e.g., one or more software applications) related to the operation of device 1000. In some implementations, memory 1030 includes one or more memories that are coupled to one or more processors (e.g., processor 1020), such as via bus 1010.

Input component 1040 enables device 1000 to receive input, such as user input and/or sensed input. For example, input component 1040 may include a touch screen, a keyboard, a keypad, a mouse, a button, a microphone, a switch, a sensor, a global positioning system sensor, an accelerometer, a gyroscope, and/or an actuator. Output component 1050 enables device 1000 to provide output, such as via a display, a speaker, and/or a light-emitting diode. Communication component 1060 enables device 1000 to communicate with other devices via a wired connection and/or a wireless connection. For example, communication component 1060 may include a receiver, a transmitter, a transceiver, a modem, a network interface card, and/or an antenna.

Device 1000 may perform one or more operations or processes described herein. For example, a non-transitory computer-readable medium (e.g., memory 1030) may store a set of instructions (e.g., one or more instructions or code) for execution by processor 1020. Processor 1020 may execute the set of instructions to perform one or more operations or processes described herein. In some implementations, execution of the set of instructions, by one or more processors 1020, causes the one or more processors 1020 and/or the device 1000 to perform one or more operations or processes described herein. In some implementations, hardwired circuitry is used instead of or in combination with the instructions to perform one or more operations or processes described herein. Additionally, or alternatively, processor 1020 may be configured to perform one or more operations or processes described herein. Thus, implementations described herein are not limited to any specific combination of hardware circuitry and software.

The number and arrangement of components shown in FIG. 10 are provided as an example. Device 1000 may include additional components, fewer components, different components, or differently arranged components than those shown in FIG. 10. Additionally, or alternatively, a set of components (e.g., one or more components) of device 1000 may perform one or more functions described as being performed by another set of components of device 1000.

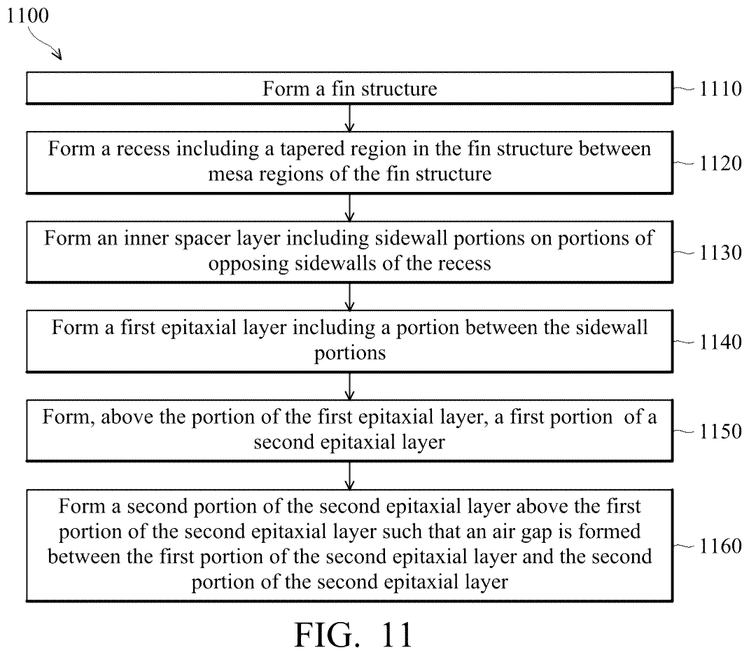

FIG. 11 is a flowchart of an example process 1100 associated with forming a semiconductor device described herein. In some implementations, one or more process blocks of FIG. 11 are performed by one or more semiconductor processing tools (e.g., one or more of the semiconductor processing tools 102-112). Additionally, or alternatively, one or more process blocks of FIG. 11 may be performed by one or more components of device 1000, such as processor 1020, memory 1030, input component 1040, output component 1050, and/or communication component 1060.

As shown in FIG. 11, process 1100 may include forming a fin structure (block 1110). For example, the one or more semiconductor processing tools 102-112 may form a fin structure 204, as described above.

As further shown in FIG. 11, process 1100 may include forming a recess including a tapered region in the fin structure between mesa regions of the fin structure (block 1120). For example, the one or more semiconductor processing tools 102-112 may form a recess (e.g., the source/drain recess 402) including a tapered region in the fin structure 204 between mesa regions 318 of the fin structure 204, as described above.

As further shown in FIG. 11, process 1100 may include forming an inner spacer layer including sidewall layer portions on portions of opposing sidewalls of the recess (block 1130). For example, the one or more semiconductor processing tools 102-112 may form an inner spacer layer 404 including sidewall layer 404b portions on portions of opposing sidewalls of the recess (e.g., the source/drain recess 402), as described above. In some implementations, the portions of the opposing sidewalls correspond to sidewalls of the mesa regions 318.

As further shown in FIG. 11, process 1100 may include forming a first epitaxial layer including a portion between the sidewall layer portions (block 1140). For example, the one or more semiconductor processing tools 102-112 may form a first epitaxial layer including a portion 508b between the sidewall layer 404b portions, as described above.

As further shown in FIG. 11, process 1100 may include forming, above the portion of the first epitaxial layer, a first portion of a second epitaxial layer (block 1150). For example, the one or more semiconductor processing tools 102-112 may form, above the portion 508b of the first epitaxial layer, a first portion 514b of a second epitaxial layer as described above.

As further shown in FIG. 11, process 1100 may include forming a second portion of the second epitaxial layer above the first portion of the second epitaxial layer such that an air gap is formed between the first portion of the second epitaxial layer and the second portion of the second epitaxial layer (block 1160). For example, the one or more semiconductor processing tools 110-112 may form a second portion 514a of the second epitaxial layer above the first portion 514b of the second epitaxial layer such that an air gap (e.g., the dielectric region 524 including a gas) is formed between the first portion 514b of the second epitaxial layer and the second portion 514a of the second epitaxial layer, as described above.

Process 1100 may include additional implementations, such as any single implementation or any combination of implementations described below and/or in connection with one or more other processes described elsewhere herein.

In a first implementation, forming the recess including the tapered region includes forming the recess to a first depth 410 below a top surface of a shallow trench isolation region 206. In some implementations, forming the sidewall layer 404b includes forming an end of the sidewall layer 404b to a second depth 406, below the top surface of the shallow trench isolation region 206, that is lesser relative to the first depth 410. In some implementations, a distance between the second depth 406 and the first depth 410 is included in a range of approximately 5 nanometers to approximately 15 nanometers.

In a second implementation, alone or in combination with the first implementation, process 1100 includes forming, in the fin structure 204, a plurality of nanostructure channels 208 and a plurality of sacrificial layers (e.g., the first layers 304) between the plurality of nanostructure channels 208, forming a source/drain region 210, removing the plurality of sacrificial layers after forming the source/drain region 210, and forming, after removing the plurality of sacrificial layers, a gate structure 212 that wraps around each of the plurality of nanostructure channels 208.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

Some implementations described herein provide techniques and semiconductor devices in which a buffer region is formed under a source/drain region of a device. The buffer region is configured to reduce, prevent, and/or block migration of dopants from the source/drain region to other areas of the device such as an adjacent mesa region of a fin structure of the device. In some implementations, a sidewall layer is between the buffer region and the mesa region. Additionally, or alternatively, a dielectric region including a dielectric gas may be between the buffer region and the source/drain region.

In this way, the sidewall layer and/or the dielectric region further reduce, prevent, and/or block migration of the dopants from the source/drain region to the other areas of the device. As a result, a performance of the device may be increased by decreasing short channel effects (e.g., DIBL), decreasing an off-current of the device, and decreasing leakage within the device.

As described in greater detail above, some implementations described herein provide a semiconductor device. The semiconductor device includes a fin structure including a mesa region and one or more nanostructure channels above the mesa region. The semiconductor device includes a buffer region adjacent to the mesa region. The semiconductor device includes a source/drain region above the buffer region and adjacent to the one or more nanostructure channels. The semiconductor device includes a sidewall layer between the buffer region and the mesa region.

As described in greater detail above, some implementations described herein provide a semiconductor device. The semiconductor device includes a fin structure including a mesa region and a plurality of nanostructure channels above the mesa region. The semiconductor device includes a buffer region adjacent to the mesa region. The semiconductor device includes a source/drain region above the buffer region and adjacent to the plurality of nanostructure channels. The semiconductor device includes a dielectric region, including a gas, between a top surface of the buffer region and a bottom surface of the source/drain region.

As described in greater detail above, some implementations described herein provide a method. The method includes forming a fin structure. The method includes forming a recess comprising a tapered region in the fin structure between mesa regions of the fin structure. The method includes forming an inner spacer layer including sidewall layer portions on portions of opposing sidewalls of the recess, where the portions of the opposing sidewalls correspond to sidewalls of the mesa regions. The method includes forming a first epitaxial layer including a portion between the sidewall layer portions. The method includes forming, above the portion of the first epitaxial layer, a first portion of a second epitaxial layer. The method includes forming a second portion of the second epitaxial layer above the first portion of the second epitaxial layer such that an air gap is formed between the first portion of the second epitaxial layer and the second portion of the second epitaxial layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a fin structure;
forming a recess comprising a tapered region in the fin structure between mesa regions of the fin structure;
forming an inner spacer layer comprising sidewall portions on portions of opposing sidewalls of the recess,
wherein the portions of the opposing sidewalls correspond to sidewalls of the mesa regions;
forming a first epitaxial layer comprising a portion between the sidewall portions;
forming, above the portion of the first epitaxial layer, a first portion of a second epitaxial layer; and
forming a second portion of the second epitaxial layer above the first portion of the second epitaxial layer such that an air gap is formed between the first portion of the second epitaxial layer and the second portion of the second epitaxial layer.

2. The method of claim 1, wherein forming the recess comprising the tapered region comprises:
forming the recess to a first depth below a top surface of a shallow trench isolation region; and
wherein forming the sidewall portions comprises:
forming ends of the sidewall portions to a second depth, below the top surface of the shallow trench isolation region, that is lesser relative to the first depth,
wherein a distance between the second depth and the first depth is included in a range of approximately 5 nanometers to approximately 15 nanometers.

3. The method claim 1, wherein the tapered region is wider at a bottom of the tapered region than at a top of the tapered region.

4. The method of claim 1, further comprising:
forming, in the fin structure, a plurality of nanostructure channels and a plurality of sacrificial layers between the plurality of nanostructure channels;
removing the plurality of sacrificial layers after forming a source/drain region; and
forming, after removing the plurality of sacrificial layers, a gate structure that wraps around each of the plurality of nanostructure channels.

5. The method of claim 4, wherein the source/drain region comprises the second portion of the second epitaxial layer and a second portion of the first epitaxial layer.

6. The method of claim 1, further comprising forming, prior to forming the first epitaxial layer, an undoped epitaxial layer between the sidewall portions,
wherein the first epitaxial layer is formed on the undoped epitaxial layer.

7. The method of claim 1, wherein the first epitaxial layer and the second epitaxial layer each comprise doped epitaxial layers.

8. The method of claim 7, wherein a dopant concentration of the second epitaxial layer is greater than a dopant concentration of the first epitaxial layer.

9. A method, comprising:
forming a fin structure comprising a plurality of nanostructure channels and a plurality of nanostructure sacrificial layers,
wherein the plurality of nanostructure channels and the plurality of nanostructure sacrificial layers are arranged in an alternating manner in a direction that is approximately perpendicular to a semiconductor substrate of a semiconductor device;
removing a portion of the fin structure between a plurality of dummy gate structures to form a source/drain recess in the fin structure,
wherein a first part of the source/drain recess is formed between regions of the semiconductor substrate under the plurality of nanostructure channels and the plurality of nanostructure sacrificial layers, and
wherein a second part of the source/drain recess is formed between the plurality of nanostructure channels and the plurality of nanostructure sacrificial layers;
forming, in the first part of the source/drain recess, an undoped semiconductor layer on a portion of the semiconductor substrate;
forming, in the first part of the source/drain recess, a first portion of a first epitaxial layer on the undoped semiconductor layer;
forming, in the second part of the source/drain recess, a second portion of the first epitaxial layer,
wherein the second portion of the first epitaxial layer extends from the plurality of nanostructure channels;
forming, in the first part of the source/drain recess, a first portion of a second epitaxial layer on the first portion of the first epitaxial layer; and
forming, in the second part of the source/drain recess, a second portion of the second epitaxial layer between surfaces of the second portion of the first epitaxial layer,
wherein a dielectric region is formed between the first portion of the second epitaxial layer and the second portion of the second epitaxial layer.

10. The method of claim 9, wherein the dielectric region comprises a gas.

11. The method of claim 9, wherein the first part of the source/drain recess has a tapered width.

12. The method of claim 11, wherein the tapered width increases from a top of the first part of the source/drain recess to a bottom of the first part of the source/drain recess.

13. The method of claim 9, wherein the undoped semiconductor layer has a concave top surface.

14. The method of claim 9, wherein the first portion of the first epitaxial layer has a concave top surface.

15. The method of claim 14, wherein a depth of the concave top surface is included in range of approximately 5 nanometers to approximately 20 nanometers.

16. A method, comprising:
forming a buffer region in a first part of a source/drain recess,
wherein the buffer region is formed on a portion of a semiconductor substrate, and
wherein the buffer region is adjacent to a mesa region below a plurality of nanostructure channels; and
forming a source/drain region in a second part of a source/drain recess;
wherein the source/drain region is above the buffer region and adjacent to the plurality of nanostructure channels, and
wherein the buffer region comprises:
an undoped semiconductor layer on the portion of the semiconductor substrate;
a first doped semiconductor layer on the undoped semiconductor layer; and
a second doped semiconductor layer on the first doped semiconductor layer.

17. The method of claim 16, further comprising forming a dielectric region between the buffer region and the source/drain region,
wherein the dielectric region comprises a gap.

18. The method of claim 17, wherein a top surface of the dielectric region extends above a top surface of the mesa region.

19. The method of claim 16, wherein the first doped semiconductor layer is over the undoped semiconductor layer along a direction perpendicular to the semiconductor substrate.

20. The method of claim 16, wherein the second doped semiconductor layer is over the first doped semiconductor layer along a direction perpendicular to the semiconductor substrate.
